(19) United States
(12) Patent Application Publication
(10) Pub. No.: US 2025/0321483 A1
(43) Pub. Date: Oct. 16, 2025

(54) RADIATION-SENSITIVE COMPOSITION AND METHOD FOR FORMING RESIST PATTERN

(71) Applicant: JSR CORPORATION, Tokyo (JP)

(72) Inventors: Katsuaki NISHIKORI, Tokyo (JP); Takuya OMIYA, Tokyo (JP); Motohiro SHIRATANI, Tokyo (JP); Asuka HACHIYA, Tokyo (JP)

(73) Assignee: JSR CORPORATION, Tokyo (JP)

(21) Appl. No.: 19/250,336

(22) Filed: Jun. 26, 2025

Related U.S. Application Data
(63) Continuation of application No. PCT/JP2023/041890, filed on Nov. 21, 2023.

(30) Foreign Application Priority Data
Dec. 28, 2022 (JP) 2022-212189

(51) Int. Cl. G03F 7/039; G03F 7/004

(52) U.S. Cl. CPC G03F 7/039; G03F 7/0042

(57) ABSTRACT

A radiation-sensitive composition includes: a polymer including a first structural unit including a partial structure obtained by substituting a hydrogen atom of a carboxy group or a hydrogen atom of a phenolic hydroxyl group, with an acid-labile group represented by formula (1); and a compound including an anionic moiety and a radiation-sensitive onium cationic moiety. The anionic moiety includes one anion group and an aromatic ring in which at least one hydrogen atom is substituted with an iodine atom. Ar¹ represents a group obtained by removing one hydrogen atom from an aromatic ring in which at least one hydrogen atom is substituted with an iodine atom.

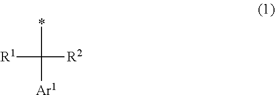

### CROSS-REFERENCE TO RELATED APPLICATIONS

The present application is a continuation application of International Patent Application No. PCT/JP2023/041890 filed Nov. 21, 2023, which claims priority to Japanese Patent Application No. 2022-212189 filed Dec. 28, 2022. The contents of these applications are incorporated herein by reference in their entirety.

### BACKGROUND OF THE DISCLOSURE

### Technical Field

The present disclosure relates to a radiation-sensitive composition and a method of forming a resist pattern.

### Discussion of the Background

A radiation-sensitive composition for use in microfabrication by lithography generates an acid at light-exposed regions upon an irradiation with a radioactive ray, e.g., an electromagnetic wave such as a far ultraviolet ray such as an ArF excimer laser beam (wavelength of 193 nm), a KrF excimer laser beam (wavelength of 248 nm), etc. or an extreme ultraviolet ray (EUV) (wavelength of 13.5 nm), or a charged particle ray such as an electron beam. A chemical reaction that originates from the acid causes a difference between the light-exposed regions and light-unexposed regions in rates of dissolution in a developer solution, whereby a resist pattern is formed on a substrate.

Such a radiation-sensitive composition is required not only to have favorable sensitivity to a radioactive ray such as an extreme ultraviolet ray and an electron beam, but also to have superiority in terms of CDU (critical dimension uniformity) performance, inhibitory ability of development defects, and the like.

Types, molecular structures, and the like of polymers, acid generating agents, and other components which may be used in radiation-sensitive compositions have been investigated to meet these requirements, and combinations thereof have been further investigated in detail (see Japanese Unexamined Patent Applications, Publication Nos. 2010-134279, 2014-224984, 2016-047815, and 2021-009357).

### SUMMARY

According to an aspect of the present disclosure, a radiation-sensitive composition includes: a polymer including a first structural unit including a partial structure obtained by substituting a hydrogen atom of a carboxy group or a hydrogen atom of a phenolic hydroxyl group, with an acid-labile group represented by formula (1); and a compound including an anionic moiety and a radiation-sensitive onium cationic moiety. The anionic moiety includes one anion group and an aromatic ring in which at least one hydrogen atom is substituted with an iodine atom. Ar¹ represents a group obtained by removing one hydrogen atom from an aromatic ring in which at least one hydrogen atom is substituted with an iodine atom. R¹ and R² each independently represent a hydrogen atom or a substituted or unsubstituted monovalent hydrocarbon group having 1 to 20 carbon atoms, wherein a case in which R¹ and R² each represent a hydrogen atom is excluded, or R¹ and R² taken together represent an alicyclic ring having 3 to 20 ring atoms, together with the carbon atom to which R¹ and R² bond. * denotes a site bonding to an ethereal oxygen atom of the carboxy group or to an oxygen atom of the phenolic hydroxyl group.

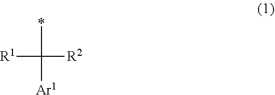

According to another aspect of the present disclosure, a radiation-sensitive composition includes: a polymer including: a structural unit including a partial structure obtained by substituting a hydrogen atom of a carboxy group or a hydrogen atom of a phenolic hydroxyl group, with an acid-labile group represented by formula (1); and a structural unit including an anionic moiety and a radiation-sensitive onium cationic moiety. The anionic moiety includes one anion group, and an aromatic ring in which at least one hydrogen atom is substituted with an iodine atom. Ar¹ represents a group obtained by removing one hydrogen atom from an aromatic ring in which at least one hydrogen atom is substituted with an iodine atom. R¹ and R² each independently represent a hydrogen atom or a substituted or unsubstituted monovalent hydrocarbon group having 1 to 20 carbon atoms, wherein a case in which R¹ and R² each represent a hydrogen atom is excluded, or R¹ and R² taken together represent an alicyclic ring having 3 to 20 ring atoms, together with the carbon atom to which R¹ and R² bond. * denotes a site bonding to an ethereal oxygen atom of the carboxy group or to an oxygen atom of the phenolic hydroxyl group.

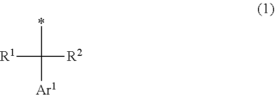

According to a further aspect of the present disclosure, a method of forming a resist pattern, includes: applying the above-described radiation-sensitive composition directly or indirectly on a substrate to form a resist film; exposing the resist film; and developing the resist film exposed.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

An embodiment of the invention is a radiation-sensitive composition containing: a polymer (hereinafter, may be also referred to as “(A) polymer” or “polymer (A)”) having a first structural unit including a partial structure obtained by substituting a hydrogen atom of a carboxy group or a hydrogen atom of a phenolic hydroxyl group, with an acid-labile group represented by the following formula (1); and a compound (hereinafter, may be also referred to as “(Z) compound” or “compound (Z)”) having: an anionic moiety including one type of anion group, and an aromatic ring in which at least one hydrogen atom is substituted with an iodine atom; and a radiation-sensitive onium cationic moiety.

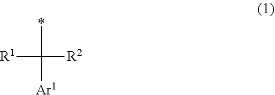

In the formula (1), Ar¹ represents a group obtained by removing one hydrogen atom from an aromatic ring in which at least one hydrogen atom is substituted with an iodine atom; R¹ and R² each independently represent a hydrogen atom or a substituted or unsubstituted monovalent hydrocarbon group having 1 to 20 carbon atoms, wherein a case in which R¹ and R² each represent a hydrogen atom is excluded, or R¹ and R² taken together represent an alicyclic ring having 3 to 20 ring atoms, together with the carbon atom to which R¹ and R² bond; and * denotes a site bonding to an ethereal oxygen atom of the carboxy group or to an oxygen atom of the phenolic hydroxyl group.

Another embodiment of the invention is a method of forming a resist pattern, the method including: applying the above-described radiation-sensitive composition directly or indirectly on a substrate to form a resist film; exposing the resist film; and developing the resist film exposed.

The radiation-sensitive composition of the present disclosure is superior in sensitivity, CDU, and inhibitory ability of development defects. The method of forming a resist pattern of the present disclosure enables forming a resist pattern that has favorable sensitivity and superior CDU, and in which occurrence of development defects is inhibited.

Hereinafter, the radiation-sensitive composition and the method of forming a resist pattern of the present disclosure will be described in detail.

With respect to descriptions of the upper limit and the lower limit of numerical ranges as referred to herein, unless otherwise specified particularly, the upper limit may have the meaning of either “no greater than” or “less than”, and the lower limit may have the meaning of either “no less than” or “greater than”. Further, as the upper limit value and the lower limit value, disclosed numerical values may be combined ad libitum. Furthermore, in a case in which a numerical range is shown using the word “to”, the numerical range is intended to include the upper limit numerical value and the lower limit numerical value. For example, the phrase “3 to 10 carbon atoms” means “3 or more and 10 or less carbon atoms”.

### Radiation-Sensitive Composition

The radiation-sensitive composition contains the polymer (A) and the compound (Z). The radiation-sensitive composition typically contains an organic solvent (hereinafter, may be also referred to as “(D) organic solvent” or “organic solvent (D)”). The radiation-sensitive composition may contain, as a suitable component, a radiation-sensitive acid generating agent (hereinafter, may be also referred to as “(B) acid generating agent” or “acid generating agent (B)”) other than the compound (Z). The radiation-sensitive composition may contain an acid diffusion control agent (hereinafter, may be also referred to as “(C) acid diffusion control agent” or “acid diffusion control agent (C)”) other than the compound (Z). The radiation-sensitive composition may contain a polymer (hereinafter, may be also referred to as “(F) polymer” or “polymer (F)”) having a percentage content of fluorine atoms higher than that of the polymer (A). The radiation-sensitive composition can contain, within a range not leading to impairment of the effects of the present invention, other optional component(s).

When the radiation-sensitive composition contains the polymer (A) and the compound (Z), the radiation-sensitive composition is superior in sensitivity, CDU, and inhibitory ability of development defects. Although not necessarily clarified and without wishing to be bound by any theory, the reason for achieving the aforementioned effects by the radiation-sensitive composition due to involving such a constitution may be presumed, for example, as in the following. It is believed that by using the polymer (A) having a specific structural unit described later in combination with the compound (Z) having a specific anion structure described later, absorption efficiency of exposure light improves, and the effective amount of the generated acid increases, thereby leading to superior sensitivity and CDU. Furthermore, it is believed that owing to improved wettability of the resist film by the polymer (A), the inhibitory ability of development defects is superior.

The radiation-sensitive composition can be prepared, for example, by: mixing, in a certain ratio, the polymer (A) and the compound (Z), as well as the acid generating agent (B), the acid diffusion control agent (C), the organic solvent (D), the polymer (F), and the other optional component(s), and the like, which are added as needed; and filtering a thus resulting mixture through a membrane filter having a pore size of no greater than 0.2 μm.

Each component contained in the radiation-sensitive composition is described below.

### (A) Polymer

The polymer (A) has a structural unit (hereinafter, may be also referred to as “structural unit (I)”) including a partial structure obtained by substituting a hydrogen atom of a carboxy group or a hydrogen atom of a phenolic hydroxyl group, with an acid-labile group (hereinafter, may be also referred to as “acid-labile group (a)”) represented by the following formula (1). The polymer (A) is a polymer, solubility of which in a developer solution is capable of being altered by an action of an acid. Although restrictive interpretation is not intended, due to the polymer (A) having the structural unit (I), the property of altering the solubility in a developer solution by an action of an acid is exhibited. The radiation-sensitive composition can contain one, or two or more types of the polymer (A).

The polymer (A) preferably further has a structural unit (hereinafter, may be also referred to as “structural unit (II)”) that includes a phenolic hydroxyl group. The polymer (A) may further have a structural unit (hereinafter, may be also referred to as “structural unit (III)”) that includes an acid-labile group other than the acid-labile group (a). The polymer (A) may further have other structural unit(s) (hereinafter, may be also referred to as “other structural unit(s)”) aside from the structural units (I) to (III). The polymer (A) can have one, or two or more types of each structural unit.

The lower limit of a proportion of the polymer (A) in the radiation-sensitive composition with respect to total components other than the organic solvent (D) contained in the radiation-sensitive composition is preferably 50% by mass, more preferably 70% by mass, and still more preferably 80% by mass. The upper limit of the proportion is preferably 99% by mass, and more preferably 95% by mass.

The lower limit of a polystyrene-equivalent weight average molecular weight (Mw) of the polymer (A) as determined by gel permeation chromatography (GPC) is preferably 1,000, more preferably 2,000, still more preferably 3,000, and even further preferably 5,000. The upper limit of the Mw is preferably 30,000, more preferably 20,000, still more preferably 10,000, and even further preferably 8,000. When the Mw of the polymer (A) falls within the above range, coating characteristics of the radiation-sensitive composition may be improved. The Mw of the polymer (A) can be adjusted by, for example, regulating the type, the amount, and the like of a polymerization initiator used in synthesis of the polymer (A). The upper limit of a ratio (hereinafter, may be also referred to as “Mw/Mn” or “polydispersity index”) of the Mw to a polystyrene-equivalent number average molecular weight (Mn) of the polymer (A) as determined by GPC is preferably 2.5, more preferably 2.0, still more preferably 1.8, and even further preferably 1.7. The lower limit of the ratio is typically 1.0, preferably 1.1, more preferably 1.2, still more preferably 1.3, and even further preferably 1.4.

### Methods for Measuring Mw and Mn

As referred to herein, the Mw and Mn of the polymer are values measured by using gel permeation chromatography (GPC) under the following conditions.

GPC columns: “G2000 HXL”×2, “G3000 HXL”×1, and “G4000 HXL”×1, each available from Tosoh Corporation
column temperature: 40° C.
elution solvent: tetrahydrofuran
flow rate: 1.0 mL/min
sample concentration: 1.0% by mass
amount of injected sample: 100 uL
detector: differential refractometer
standard substance: mono-dispersed polystyrene

The polymer (A) can be synthesized by, for example, polymerizing a monomer that gives each structural unit in accordance with a well-known procedure.

Each structural unit included in the polymer (A) is described below.

### Structural Unit (I)

The structural unit (I) is a structural unit including a partial structure obtained by substituting a hydrogen atom of a carboxy group or a hydrogen atom of a phenolic hydroxyl group, with an acid-labile group (acid-labile group (a)) represented by the following formula (1). The polymer (A) can have one, or two or more types of the structural unit (I).

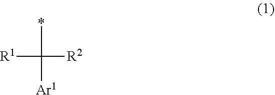

In the formula (1), Ar¹ represents a group obtained by removing one hydrogen atom from an aromatic ring in which at least one hydrogen atom is substituted with an iodine atom; R¹ and R² each independently represent a hydrogen atom or a substituted or unsubstituted monovalent hydrocarbon group having 1 to 20 carbon atoms, wherein a case in which R¹ and R² each represent a hydrogen atom is excluded, or R¹ and R² taken together represent an alicyclic ring having 3 to 20 ring atoms, together with the carbon atom to which R¹ and R² bond; and * denotes a site bonding to an ethereal oxygen atom of the carboxy group or to an oxygen atom of the phenolic hydroxyl group.

The structural unit (I) is a structural unit that includes the acid-labile group (a). The term “acid-labile group” as referred to herein means a group that substitutes for a hydrogen atom in a carboxy group or a hydrogen atom in a hydroxy group, and is capable of being dissociated by an action of an acid to give a carboxy group or a hydroxy group. The acid-labile group (a) is a group that substitutes for a hydrogen atom included in the carboxy group or a hydrogen atom included in the phenolic hydroxyl group in the structural unit (I). In other words, in the structural unit (I), the acid-labile group (a) bonds to the ethereal oxygen atom of the carbonyloxy group or to the oxygen atom of the phenolic hydroxyl group. The term “phenolic hydroxyl group” as referred to herein is not limited to a hydroxy group directly bonding to a benzene ring, and means any hydroxy group directly bonding to an aromatic ring in general.

Owing to the polymer (A) having the structural unit (I), the acid-labile group (a) is dissociated from the structural unit (I) by an action of the acid generated from the compound (Z), the acid generating agent (B), etc. upon exposure, whereby a difference is generated in the solubility of the polymer (A) in the developer solution, between light-exposed regions and light-unexposed regions, and thus forming a resist pattern is enabled. The feature that the polymer (A) includes the acid-labile group (a) in the structural unit (I) is believed to be one factor in the radiation-sensitive composition exhibiting superior sensitivity, CDU, and inhibitory ability of development defects.

The term “group obtained by removing X hydrogen atom(s) from a ring structure” as referred to herein means a group obtained by removing X hydrogen atom(s) bonding to atom(s) constituting the ring structure. The “ring structure” encompasses both an “alicyclic ring” and an “aromatic ring”. The “alicyclic ring” encompasses both an “aliphatic hydrocarbon ring” and an “aliphatic heterocyclic ring”. Of the alicyclic structures, a polycyclic one containing both the aliphatic hydrocarbon ring and the aliphatic heterocyclic ring falls under the “aliphatic heterocyclic ring”. The “aromatic ring” encompasses both an “aromatic hydrocarbon ring” and an “aromatic heterocyclic ring”. Of the aromatic rings, a polycyclic one containing both the aromatic hydrocarbon ring and the aromatic heterocyclic ring falls under the “aromatic heterocyclic ring”.

The number of ring atoms of the aromatic ring that gives Ar¹ is not particularly limited and is, for example, 5 to 30, and preferably 5 to 20. The number of “ring atoms” as referred to herein means the number of atoms constituting a ring structure, and in the case of a polycyclic ring, the number of “ring atoms” means the number of atoms constituting the polycyclic ring. The “polycyclic ring” encompasses not only a spiro-type polycyclic ring in which two rings have one shared atom and a condensed polycyclic ring in which two rings have two shared atoms, but also a ring-assembled polycyclic ring in which two rings are connected by a single bond without having any shared atom.

The aromatic ring that gives Ar¹ is exemplified by an aromatic hydrocarbon ring having 6 to 30 ring atoms, and an aromatic heterocyclic ring having 5 to 30 ring atoms.

Examples of the aromatic hydrocarbon ring having 6 to 30 ring atoms include: a benzene ring; condensed polycyclic aromatic hydrocarbon rings such as a naphthalene ring, an anthracene ring, a fluorene ring, a biphenylene ring, a phenanthrene ring, and a pyrene ring; and ring-assembled aromatic hydrocarbon rings such as a biphenyl ring, a terphenyl ring, a binaphthalene ring, and a phenylnaphthalene ring.

Examples of the aromatic heterocyclic ring having 5 to 30 ring atoms include: oxygen atom-containing aromatic heterocyclic rings such as a furan ring, a pyran ring, a benzofuran ring, and a benzopyran ring; nitrogen atom-containing aromatic heterocyclic rings such as a pyrrole ring, a pyridine ring, a pyrimidine ring, an indole ring, and a quinoline ring; and sulfur atom-containing aromatic heterocyclic rings such as a thiophene ring and a dibenzothiophene ring.

The aromatic ring that gives Ar¹ is preferably the aromatic hydrocarbon ring having 6 to 30 ring atoms, more preferably a benzene ring or the condensed polycyclic aromatic hydrocarbon ring, and still more preferably a benzene ring or a naphthalene ring.

The aromatic ring that gives Ar¹ has at least one iodine atom bonded to the aromatic ring. In other words, at least one hydrogen atom bonding to an atom constituting the aromatic ring that gives Ar¹ has been substituted with an iodine atom. The number of the substitution(s) with iodine atom(s) is not particularly limited, and can be determined ad libitum as long as it is no less than 1. The number is, e.g., 1 to 5, and preferably 1 to 3. The number of the substitution(s) with iodine atom(s) is preferably no less than 2 because at least one of the sensitivity and the inhibitory ability of development defects tends to more improve, as compared with the case in which the number of the substitution(s) with iodine atom(s) is 1.

The aromatic ring that gives Ar¹ may further have at least one substituent, other than an iodine atom, bonded to the aromatic ring. The substituent is exemplified by: halogen atoms other than an iodine atom; a hydroxy group; a carboxy group; a cyano group; a nitro group; an alkyl group; a fluorinated alkyl group (a group obtained by substituting a fluorine atom for at least one hydrogen atom included in an alkyl group); an alkoxy group; an alkoxycarbonyl group; an alkoxycarbonyloxy group; an acyl group; an acyloxy group; and an oxo group (═O). The substituent is preferably an alkoxy group, and more preferably a methoxy group.

The monovalent hydrocarbon group having 1 to 20 carbon atoms, which may be represented by R¹ or R² is exemplified by a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

The number of “carbon atoms” means the number of carbon atoms constituting a group. The “hydrocarbon group” encompasses an “aliphatic hydrocarbon group” and an “aromatic hydrocarbon group”. The “aliphatic hydrocarbon group” encompasses a “chain hydrocarbon group” and an “alicyclic hydrocarbon group”. In another light, the “aliphatic hydrocarbon group” encompasses a “saturated hydrocarbon group” and an “unsaturated hydrocarbon group”. The “chain hydrocarbon group” as referred to herein means a hydrocarbon group not having a ring structure but being constituted of only a chain structure, and may be exemplified by both a linear hydrocarbon group and a branched hydrocarbon group. The “alicyclic hydrocarbon group” as referred to herein means a hydrocarbon group having, as a ring structure, not an aromatic ring but an alicyclic ring alone, and may be exemplified by both a monocyclic alicyclic hydrocarbon group and a polycyclic alicyclic hydrocarbon group. With regard to this, it is not necessary for the alicyclic hydrocarbon group to be constituted of only an alicyclic structure; it may have a chain structure in a part thereof. The “aromatic hydrocarbon group” as referred to herein means a hydrocarbon group that includes an aromatic ring as a ring structure. With regard to this, it is not necessary for the aromatic hydrocarbon group to be constituted of only an aromatic ring, and it may have a chain structure or an alicyclic ring in a part thereof.

Examples of the monovalent chain hydrocarbon group having 1 to 20 carbon atoms include: alkyl groups such as a methyl group, an ethyl group, an n-propyl group, an i-propyl group, an n-butyl group, a sec-butyl group, an isobutyl group, and a tert-butyl group; alkenyl groups such as an ethenyl group, a propenyl group, a butenyl group, and a 2-methylprop-1-en-1-yl group; and alkynyl groups such as an ethynyl group, a propynyl group, and a butynyl group.

Examples of the monovalent alicyclic hydrocarbon group having 3 to 20 carbon atoms include: monocyclic alicyclic saturated hydrocarbon groups such as a cyclopentyl group and a cyclohexyl group; polycyclic alicyclic saturated hydrocarbon groups such as a norbornyl group, an adamantyl group, a tricyclodecyl group, and a tetracyclododecyl group; monocyclic alicyclic unsaturated hydrocarbon groups such as a cyclopentenyl group and a cyclohexenyl group; and polycyclic alicyclic unsaturated hydrocarbon groups such as a norbornenyl group, a tricyclodecenyl group, and a tetracyclododecanyl group.

Examples of the monovalent aromatic hydrocarbon group having 6 to 20 carbon atoms include: aryl groups such as a phenyl group, a tolyl group, a xylyl group, a naphthyl group, and an anthryl group; and aralkyl groups such as a benzyl group, a phenethyl group, a naphthylmethyl group, and an anthrylmethyl group.

The monovalent hydrocarbon group having 1 to 20 carbon atoms may further have at least one substituent bonded to the monovalent hydrocarbon group. The substituent is exemplified by: halogen atoms such as a fluorine atom and an iodine atom; a hydroxy group; a carboxy group; a cyano group; a nitro group; an alkoxy group; an alkoxycarbonyl group; an alkoxycarbonyloxy group; an acyl group; and an acyloxy group. The substituent is preferably an alkoxy group, and more preferably a methoxy group.

The above-described hydrocarbon group is preferably a monovalent chain hydrocarbon group having 1 to 20 carbon atoms, more preferably an alkyl group, and still more preferably a methyl group, an ethyl group, or an i-propyl group.

Examples of the alicyclic ring having 3 to 20 ring atoms and represented by R¹ and R² taken together, together with the carbon atom to which R¹ and R² bond include aliphatic hydrocarbon rings, e.g.: monocyclic saturated alicyclic rings such as a cyclopropane ring, a cyclobutane ring, a cyclopentane ring, and a cyclohexane ring; polycyclic saturated alicyclic rings such as a norbornane ring, an adamantane ring, a tricyclodecane ring, and a tetracyclododecane ring; monocyclic unsaturated alicyclic rings such as a cyclopropene ring, a cyclobutene ring, a cyclopentene ring, and a cyclohexene ring; polycyclic unsaturated alicyclic rings such as a norbornene ring, a tricyclodecene ring, and a tetracyclododecene ring; and the like.

The above-described alicyclic ring is preferably an aliphatic hydrocarbon ring having 3 to 20 ring atoms, more preferably a saturated aliphatic hydrocarbon ring having 3 to 20 ring atoms, still more preferably a monocyclic saturated aliphatic hydrocarbon ring having 3 to 20 ring atoms, and even further preferably a cyclopentane ring or a cyclohexane ring.

A case in which R¹ and R² each represent a hydrogen atom is excluded. Although restrictive interpretation is not intended, in a case in which R¹ and R² each represent a hydrogen atom, the carbon atom in the acid-labile group (a) bonding to the ethereal oxygen atom of the carboxy group or to the oxygen atom of the phenolic hydroxyl group (the carbon atom bonding to * in the above formula (1)) is a primary carbon atom, whereby acid-lability is not exhibited. In a case of excluding the case in which R¹ and R² each represent a hydrogen atom, the carbon atom bonding to * in the above formula (1) is a secondary or tertiary carbon atom, whereby acid-lability is exhibited. The carbon atom bonding to * in the above formula (1) is preferably a tertiary carbon atom. The carbon atom being a tertiary carbon atom is preferred because the CDU tends to more improve, compared with the case of being a secondary carbon atom. It is to be noted that the degree of a carbon atom typically indicates the number of carbon atoms directly bonded to the carbon atom. Herein, the degree of the carbon atom is determined based on a state of bonding to the oxygen atom.

The acid-labile group (a) is preferably a group that substitutes for a hydrogen atom included in the carboxy group in the structural unit (I). In other words, in the structural unit (I), the acid-labile group (a) preferably bonds to the ethereal oxygen atom of the carbonyloxy group.

The acid-labile group (a) is preferably groups represented by the following formulae (1-1) to (1-11).

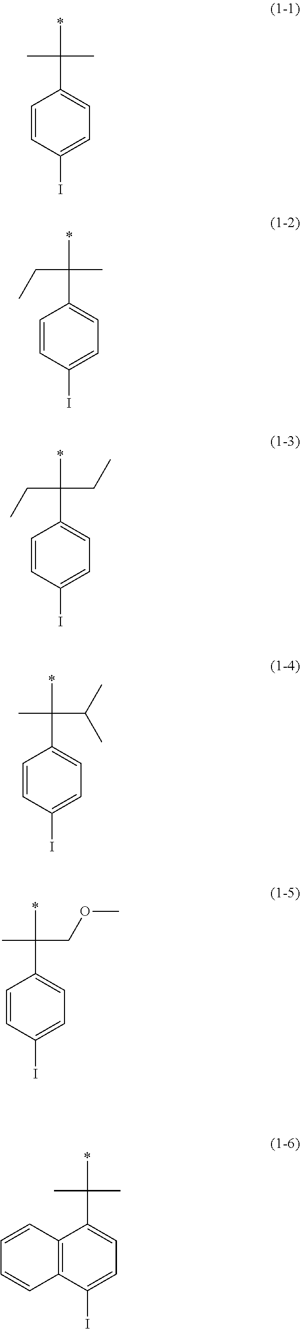

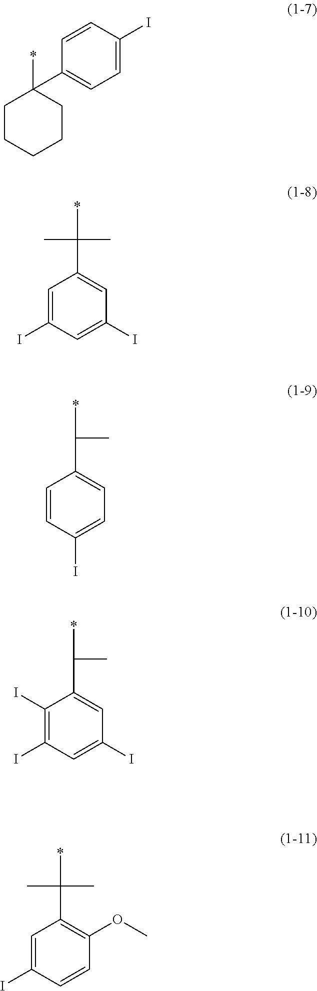

In the above formulae (1-1) to (1-11), * is as defined in the above formula (1).

The structural unit (I) is exemplified by a structural unit represented by the following formula (I-1) or (I-2).

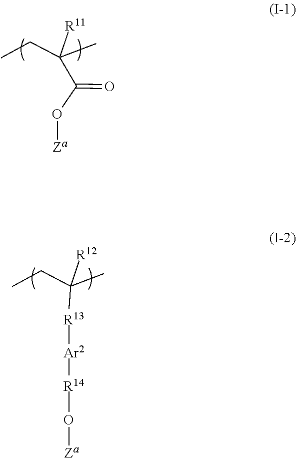

In the above formulae (I-1) and (1-2), Z^{a} represents the acid-labile group (acid-labile group (a)) represented by the above formula (1).

In the above formula (I-1), R¹¹ represents a hydrogen atom, a fluorine atom, a methyl group, or a trifluoromethyl group.

In the above formula (I-2), R¹² represents a hydrogen atom or a methyl group; R¹³ represents a single bond, —O—, —COO—, or —CONH—; Ar² represents a group obtained by removing two hydrogen atoms from a substituted or unsubstituted aromatic ring; and R¹⁴ represents a single bond or —CO—.

R¹¹ represents, in light of a degree of copolymerization of a monomer that gives the structural unit (I), preferably a hydrogen atom or a methyl group.

R¹² represents preferably a hydrogen atom.

R¹³ represents preferably a single bond.

The number of ring atoms and the type of the aromatic ring that gives Ar² are exemplified by those exemplified for the aromatic ring that gives Ar¹ in the above formula (1). The aromatic ring that gives Ar² is preferably an aromatic hydrocarbon ring having 6 to 30 ring atoms, and more preferably a benzene ring.

The aromatic ring that gives Ar² may further have at least one substituent bonded to the aromatic ring. The substituent is exemplified by: halogen atoms such as a fluorine atom and an iodine atom; a hydroxy group; a carboxy group; a cyano group; a nitro group; an alkyl group; a fluorinated alkyl group (a group obtained by substituting a fluorine atom for at least one hydrogen atom included in an alkyl group); an alkoxy group; an alkoxycarbonyl group; an alkoxycarbonyloxy group; an acyl group; an acyloxy group; and an oxo group (═O).

R¹⁴ represents preferably a single bond.

The lower limit of a proportion of the structural unit (I) included in the polymer (A) with respect to total structural units constituting the polymer (A) is preferably 5 mol %, more preferably 10 mol %, still more preferably 15 mol %, and even further preferably 20 mol %.

The upper limit of the proportion is preferably 80 mol %, more preferably 70 mol %, and still more preferably 60 mol %. When the proportion of the structural unit (I) falls within the above range, the sensitivity, the CDU, and the inhibitory ability of development defects of the radiation-sensitive composition may be more improved. Furthermore, a case in which the proportion of the structural unit (I) is greater than 20 mol % is preferred because the sensitivity and the inhibitory ability of development defects tend to be more improved, as compared with a case in which the proportion is no greater than 20 mol %.

The polymer (A) having the structural unit (I) can be synthesized by polymerizing, in accordance with a well-known procedure, a monomer (hereinafter, may be also referred to as “monomer (X)”) that gives the structural unit (I).

### Structural Unit (II)

The structural unit (II) is a structural unit that includes a phenolic hydroxyl group. The polymer (A) can have one, or two or more types of the structural unit (II).

In the case of KrF exposure, EUV exposure, or electron beam exposure, the sensitivity of the radiation-sensitive composition to the exposure light can be more enhanced due to the polymer (A) having the structural unit (II). Therefore, in the case in which the polymer (A) has the structural unit (II), the radiation-sensitive composition can be suitably used as a radiation-sensitive composition for exposure to KrF, for exposure to EUV, or for exposure to an electron beam.

The structural unit (II) is exemplified by a structural unit represented by the following formula (II).

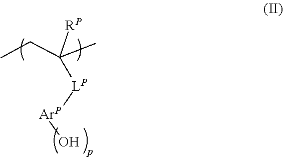

In the above formula (II), R^{P} represents a hydrogen atom, a fluorine atom, a methyl group, or a trifluoromethyl group; L^{P} represents a single bond, —COO—, —O—, or —CONH—; Ar^{P} represents a group obtained by removing (p+1) hydrogen atoms from a substituted or unsubstituted aromatic ring; and p is an integer of 1 to 3.

R^{P} represents, in light of a degree of copolymerization of a monomer that gives the structural unit (II), preferably a hydrogen atom or a methyl group.

L^{P} represents preferably a single bond or —COO—, and more preferably a single bond.

The number of ring atoms and the type of the aromatic ring that gives Ar^{P} are exemplified by those exemplified for the aromatic ring that gives Ar¹ in the above formula (1). The aromatic ring that gives Ar^{P} is preferably an aromatic hydrocarbon ring having 6 to 30 ring atoms, and more preferably a benzene ring.

The aromatic ring that gives Ar^{P} may further have at least one substituent bonded to the aromatic ring. The substituent is exemplified by those exemplified as the substituent that may be incorporated in the aromatic ring that gives Ar² in the above formula (I-2).

p is preferably 1 or 2. The case in which p is 1 is preferred because the CDU of the radiation-sensitive composition tends to be more improved, as compared with the case in which p is 2. The case in which p is 2 is preferred because the sensitivity and the inhibitory ability of development defects of the radiation-sensitive composition tend to be more improved, as compared with the case in which p is 1.

The structural unit (II) is exemplified by structural units represented by the following formulae (II-1) to (II-18).

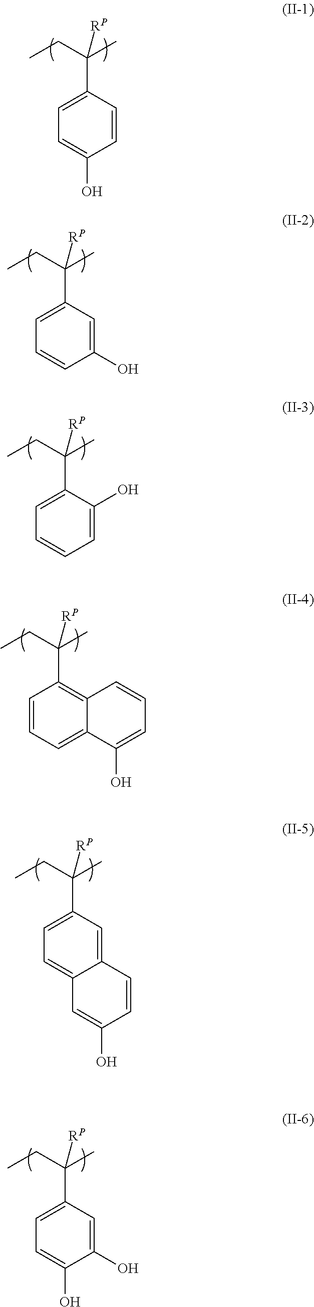

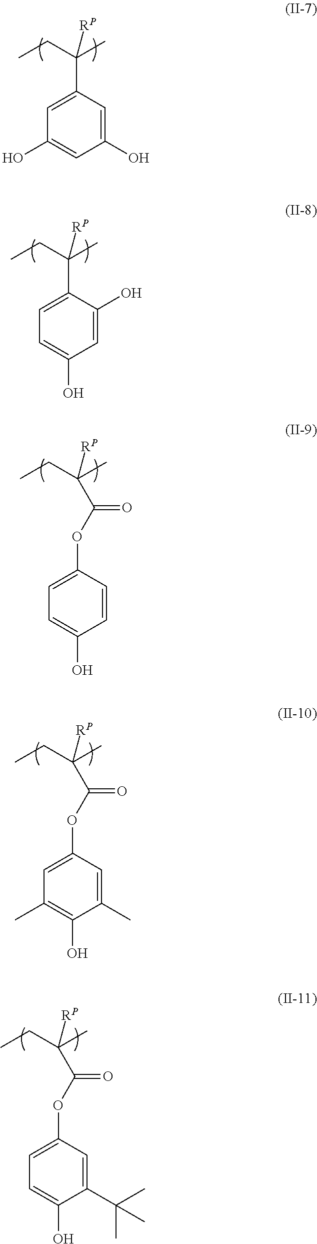

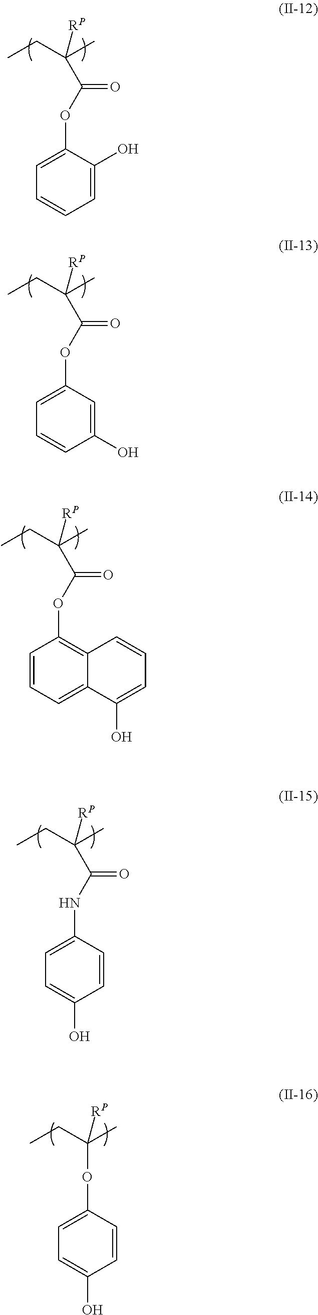

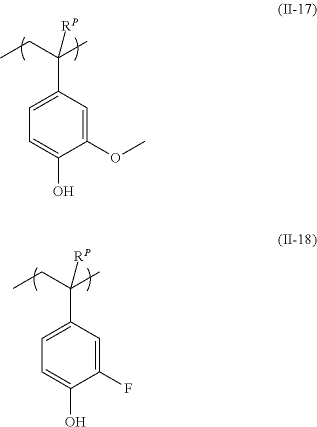

In the above formulae (II-1) to (II-18), R^{P} is as defined in the above formula (II).

In the case in which the polymer (A) has the structural unit (II), the lower limit of a proportion of the structural unit (II) included in the polymer (A) with respect to total structural units constituting the polymer (A) is preferably 10 mol %, more preferably 20 mol %, and still more preferably 25 mol %. The upper limit of the proportion is preferably 70 mol %, more preferably 60 mol %, and still more preferably 50 mol %. When the proportion of the structural unit (II) falls within the above range, the sensitivity, the CDU, and the inhibitory ability of development defects of the radiation-sensitive composition may be more improved. Furthermore, a case in which the proportion of the structural unit (II) is greater than 25 mol % is preferred because the sensitivity tends to be more superior, as compared with a case in which the proportion is no greater than 25 mol %.

### Structural Unit (III)

The structural unit (III) is a structural unit that includes an acid-labile group (hereinafter, may be also referred to as “acid-labile group (b)”) other than the acid-labile group (a). More specifically, the structural unit (III) is a structural unit including a partial structure obtained by substituting a hydrogen atom of a carboxy group or a hydrogen atom of a phenolic hydroxyl group, with the acid-labile group (b). The structural unit (III) is a structural unit different from the structural unit (I). The polymer (A) can have one, or two or more types of the structural unit (III).

When the polymer (A) has the structural unit (III), the process window can be adjusted.

The acid-labile group (b) is a group that substitutes for a hydrogen atom included in the carboxy group or a hydrogen atom included in the phenolic hydroxyl group in the structural unit (III). In other words, in the structural unit (III), the acid-labile group (b) bonds to an ethereal oxygen atom of the carbonyloxy group or to an oxygen atom of the phenolic hydroxyl group.

The acid-labile group (b) is not particularly limited as long as it is a group other than the acid-labile group (a). The acid-labile group (b) is exemplified by groups (hereinafter, may be also referred to as “acid-labile groups (b-1) to (b-3)”) represented by the following formulae (b-1) to (b-3).

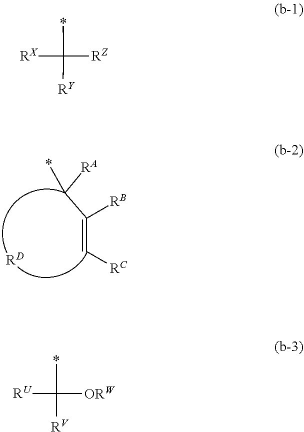

In the above formulae (b-1) to (b-3), * denotes a site bonding to the ethereal oxygen atom of the carboxy group or to the oxygen atom of the phenolic hydroxyl group.

In the above formula (b-1), R^{X} represents a substituted or unsubstituted monovalent hydrocarbon group having 1 to 20 carbon atoms; and R^{Y} and R^{Z} each independently represent a monovalent hydrocarbon group having 1 to 20 carbon atoms, or R^{Y} and R^{Z} taken together represent a saturated alicyclic ring having 3 to 20 ring atoms, together with the carbon atom to which R^{Y} and R^{Z} bond, wherein a combination of R^{X}, R^{Y}, and R^{Z} that can be included in the above formula (1) is excluded.

In the above formula (b-2), R^{A} represents a hydrogen atom; R^{B} and R^{C} each independently represent a hydrogen atom or a monovalent hydrocarbon group having 1 to 20 carbon atoms; and RD represents a divalent hydrocarbon group having 1 to 20 carbon atoms, and constituting an unsaturated alicyclic ring having 4 to 20 ring atoms, together with the three carbon atoms to which R^{A}, R^{B}, and R^{C} bond, respectively.

In the above formula (b-3): R^{U} and R^{V} each independently represent a hydrogen atom or a monovalent hydrocarbon group having 1 to 20 carbon atoms, and R^{W} represents a monovalent hydrocarbon group having 1 to 20 carbon atoms, or R^{U} and R^{V} taken together represent a saturated alicyclic ring having 3 to 20 ring atoms, together with the carbon atom to which R^{U} and R^{V} bond; or R^{U} and R^{W} taken together represent an oxygen atom-containing aliphatic heterocyclic ring having 4 to 20 ring atoms, together with the carbon atom to which R^{U} bonds and with the oxygen atom to which R^{W} bonds.

The monovalent hydrocarbon group having 1 to 20 carbon atoms, which may be represented by R^{X}, R^{Y}, R^{Z}, R^{B}, R^{C}, R^{U}, R^{V}, or R^{W}, is exemplified by those exemplified as the monovalent hydrocarbon group having 1 to 20 carbon atoms, which may be represented by R¹ or R², in the above formula (1).

The substituent that may be incorporated in the hydrocarbon group represented by R^{X} is exemplified by those exemplified as the substituent that may be incorporated in the monovalent hydrocarbon group having 1 to 20 carbon atoms, which may be represented by R¹ or R² in the above formula (1).

The saturated alicyclic ring having 3 to 20 ring atoms, which may be represented by R^{Y} and R^{Z} taken together, together with the carbon atom to which R^{Y} and R^{Z} bond; and the saturated alicyclic ring having 3 to 20 ring atoms, which may be represented by R^{U} and R^{V} taken together, together with the carbon atom to which R^{U} and R^{V} bond are exemplified by the saturated alicyclic rings exemplified as the alicyclic ring having 3 to 20 ring atoms, which may be represented by R¹ and R² in the above formula (1) taken together, together with the carbon atom to which R¹ and R² bond.

The divalent hydrocarbon group having 1 to 20 carbon atoms and represented by RD is exemplified by a group obtained by removing one hydrogen atom from a group exemplified as the monovalent hydrocarbon group having 1 to 20 carbon atoms, which may be represented by the above-described R^{X}, R^{Y}, R^{Z}, R^{B}, R^{C}, R^{U}, R^{Y}, or R^{W}.

Examples of the unsaturated alicyclic ring having 4 to 20 ring atoms and represented by RD and the three carbon atoms to which R^{A}, R^{B}, and R^{C} bond, respectively, include: monocyclic unsaturated alicyclic structures such as a cyclobutene structure, a cyclopentene structure, and a cyclohexene structure; polycyclic unsaturated alicyclic structures such as a norbornene structure; and the like.

Examples of the oxygen atom-containing aliphatic heterocyclic ring having 4 to 20 ring atoms, which may be represented by R^{U} and R^{W} taken together, together with the carbon atom to which R^{U} bonds and with the oxygen atom to which R^{W} bonds, include an oxacyclobutane ring, an oxacyclopentane ring, an oxacyclohexane ring, an oxacyclobutane ring, an oxacyclopentane ring, an oxacyclohexane ring, and the like.

In the case in which R^{Y} and R^{Z} each represent a monovalent hydrocarbon group having 1 to 20 carbon atoms, R^{Y} and R^{Z} each represent preferably a chain hydrocarbon group, which is preferably an alkyl group, and is more preferably a methyl group. In this case, R^{X} represents: preferably a substituted or unsubstituted chain hydrocarbon group, or a substituted or unsubstituted aromatic hydrocarbon group; more preferably an unsubstituted alkyl group, or a substituted or unsubstituted aryl group; and still more preferably a methyl group, a phenyl group, or a 4-fluorophenyl group.

In the case in which R^{Y} and R^{Z} taken together represent a saturated alicyclic ring having 3 to 20 ring atoms, together with the carbon atom to which R^{Y} and R^{Z} bond, the saturated alicyclic ring is preferably a monocyclic saturated alicyclic ring, and more preferably a cyclopentane ring or a cyclohexane ring. In this case, R^{X} represents: preferably a substituted or unsubstituted chain hydrocarbon group, or a substituted or unsubstituted aromatic hydrocarbon group; more preferably an unsubstituted alkyl group, or an unsubstituted aryl group; and still more preferably a methyl group, an ethyl group, an i-propyl group, a tert-butyl group, or a phenyl group.

It is preferred that R^{Y} and R^{Z} taken together represent a saturated alicyclic ring having 3 to 20 ring atoms, together with the carbon atom to which R^{Y} and R^{Z} bond because more improving the CDU of the radiation-sensitive composition tends to be enabled. In this case, it is further preferred that R^{X} represents a substituted or unsubstituted aromatic hydrocarbon group because more improving the sensitivity of the radiation-sensitive composition tends to be enabled.

R^{B} represents preferably a hydrogen atom.

R^{C} represents preferably a chain hydrocarbon group, more preferably an alkyl group, and still more preferably a methyl group.

The unsaturated alicyclic ring having 4 to 20 ring atoms and represented by RD together with the three carbon atoms to which R^{A}, R^{B}, and R^{C} bond, respectively, is preferably a monocyclic unsaturated alicyclic ring, and more preferably a cyclopentene ring or a cyclohexene ring.

The acid-labile group (b) is preferably the acid-labile group (b-1) or (b-2).

The acid-labile group (b-1) is exemplified by groups represented by the following formulae (b-1-1) to (b-1-8). The acid-labile group (b-2) is exemplified by a group represented by the following formula (b-2-1).

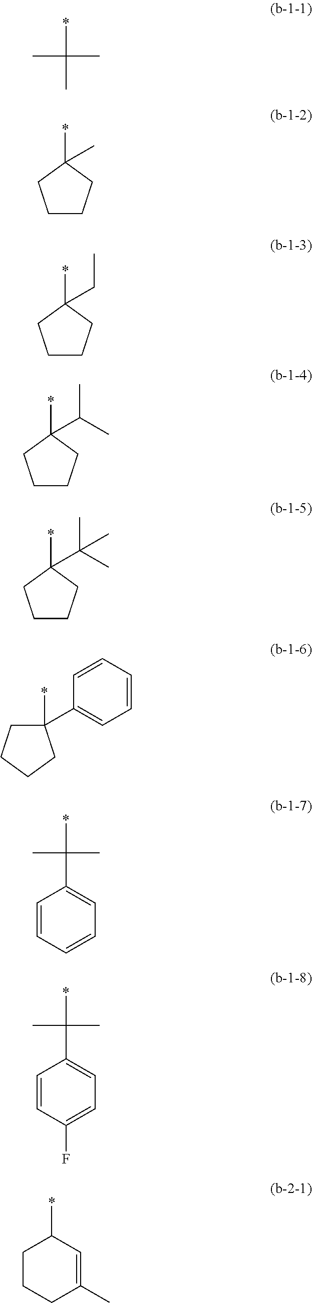

In the above formulae (b-1-1) to (b-1-8) and (b-2-1), * is as defined in the above formulae (b-1) and (b-2).

The structural unit (III) is exemplified by a structural unit represented by the following formula (III-1) or (III-2).

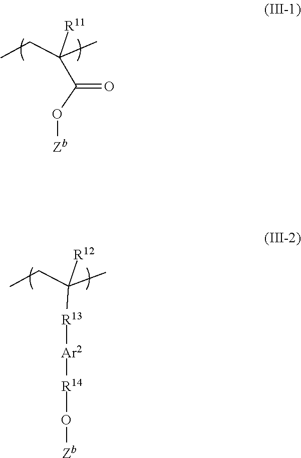

In the above formulae (III-1) and (III-2), Z^{b} represents a group (the acid-labile group (b)) represented by any one of the above formulae (b-1) to (b-3).

In the above formula (III-1), R¹¹ is as defined in the above formula (I-1). In the above formula (III-2), R¹², R¹³, Ar², and R¹⁴ are as defined in the above formula (I-2).

Preferred modes of R¹¹ in the above formula (III-1), and R¹², R¹³, Ar², and R¹⁴ in the above formula (III-2) are also the same as those in the above formulae (1-1) and (I-2).

In the case in which the polymer (A) has the structural unit (III), the lower limit of a proportion of the structural unit (III) in the polymer (A) with respect to total structural units constituting the polymer (A) is preferably 5 mol %, more preferably 10 mol %, and still more preferably 15 mol %. The upper limit of the proportion is preferably 60 mol %, more preferably 50 mol %, and still more preferably 40 mol %.

Furthermore, in the case in which the polymer (A) has the structural unit (III), the upper limit of a proportion of the structural unit (III) in the polymer (A), with respect to the structural units included in the polymer (A) and including the acid-labile groups (i.e., the total of the structural unit (I) and the structural unit (III)), is preferably 90 mol %, more preferably 65 mol %, still more preferably 40 mol %, and particularly preferably 20 mol %. The lower limit of the proportion may encompass greater than 0 mol %. It is to be noted that because in some modes, the polymer (A) may have no structural unit (III), the proportion of the structural unit (I) in the polymer (A) with respect to the structural units included in the polymer (A) and including the acid-labile groups may be 100 mol %.

### Other Structural Unit(s)

The other structural unit(s) is/are structural unit(s) other than the structural units (I) to (III). The other structural unit(s) is/are exemplified by: a structural unit (hereinafter, may be also referred to as “structural unit (IV)”) that includes a lactone structure, a cyclic carbonate structure, a sultone structure, or a combination of the same; and a structural unit (hereinafter, may be also referred to as “structural unit (V)”) that includes an alcoholic hydroxyl group. The polymer (A) may have, other than these structural units, a structural unit that includes a partial structure that generates an acid upon an irradiation with a radioactive ray.

### Structural Unit (IV)

The structural unit (IV) is a structural unit that includes a lactone structure, a cyclic carbonate structure, a sultone structure, or a combination of the same. When the polymer (A) further has the structural unit (IV), adhesiveness to a substrate can be improved. The polymer (A) can contain one, or two or more types of the structural unit (IV).

The structural unit (IV) is exemplified by structural units represented by the following formulae, and the like.

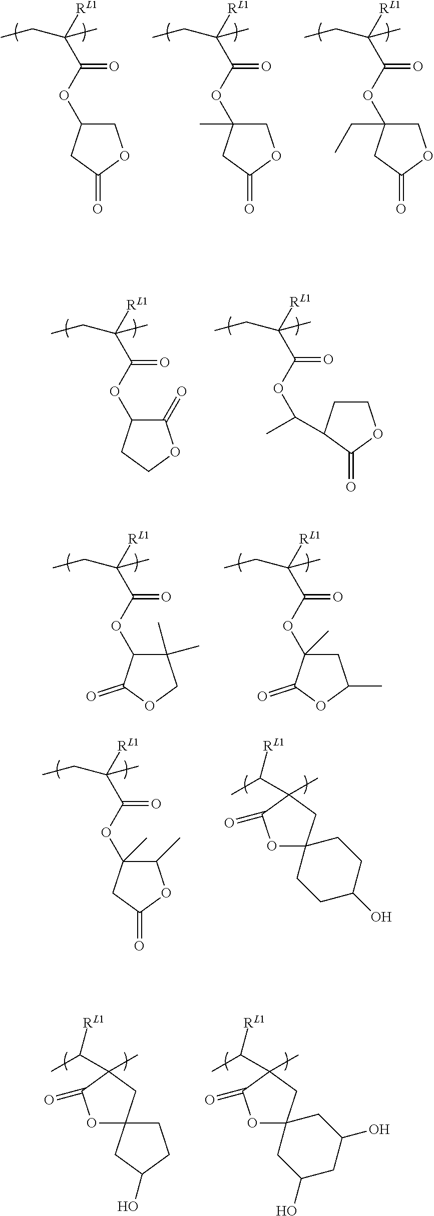

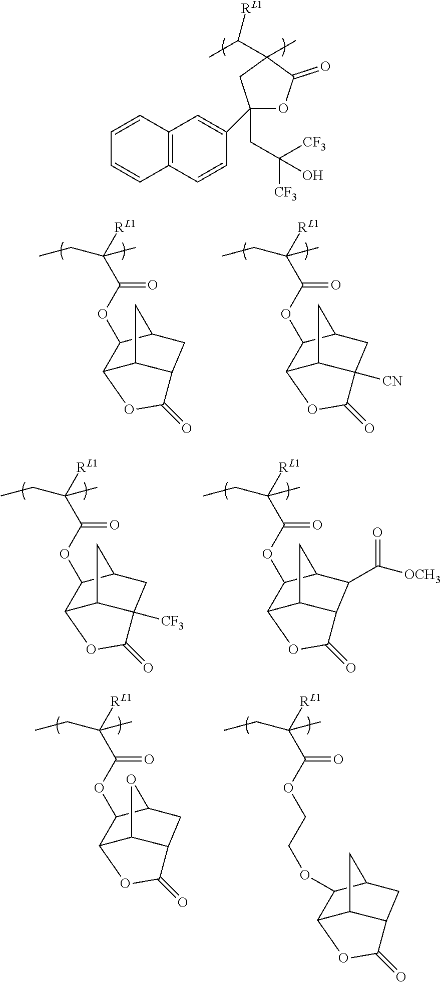

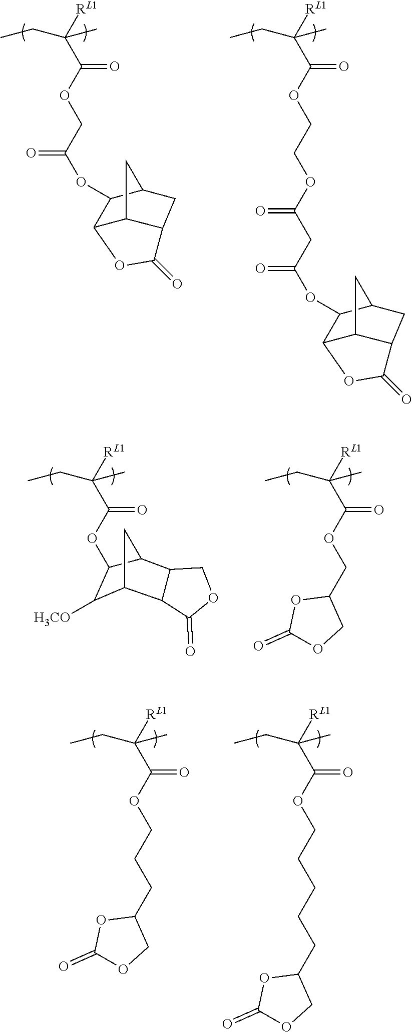

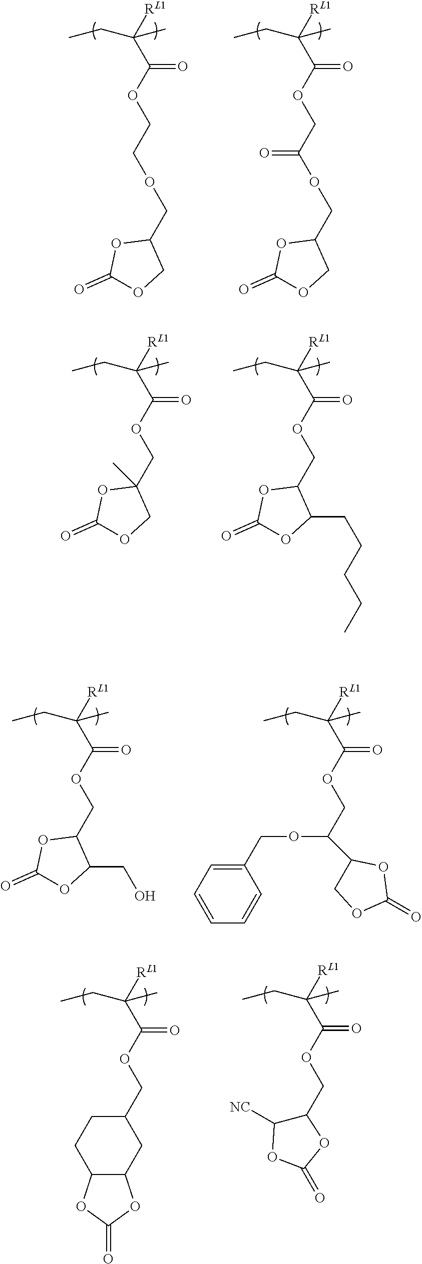

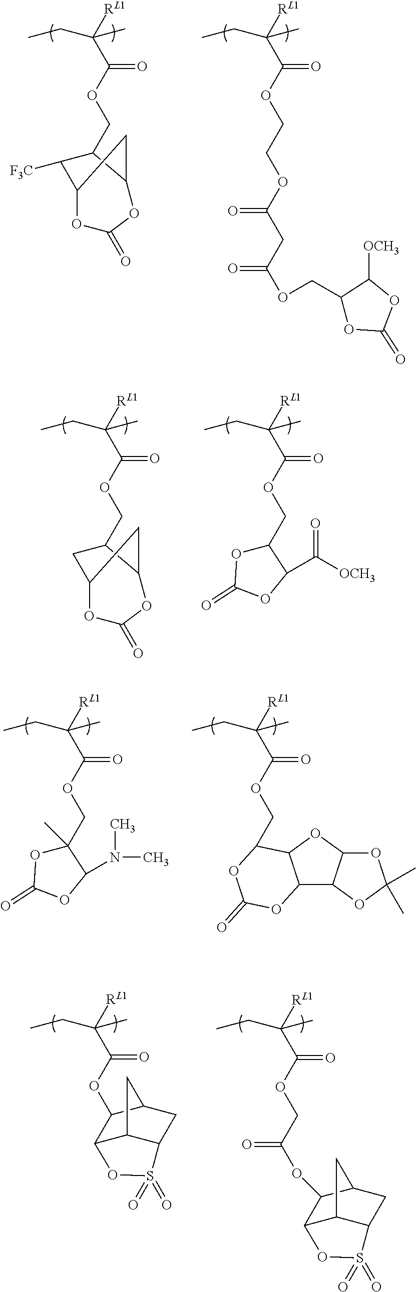

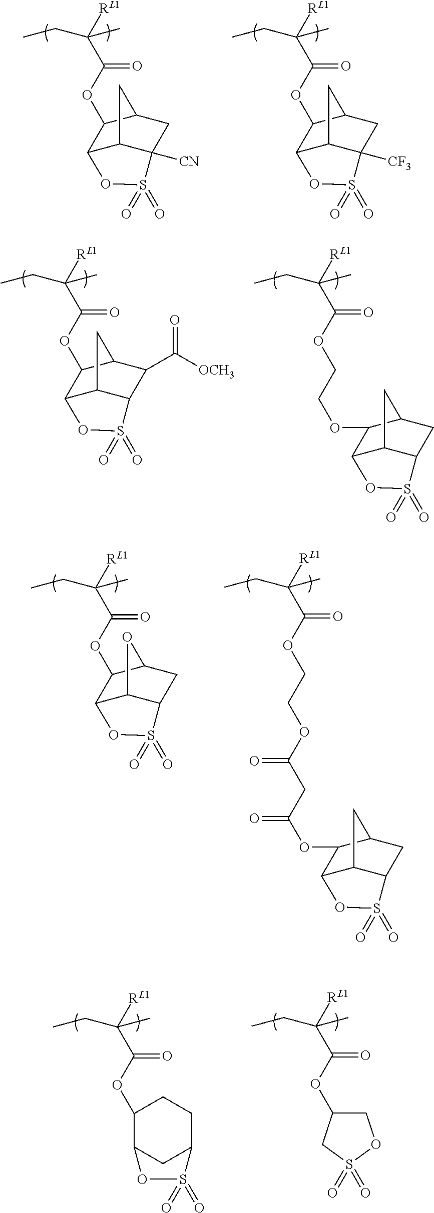

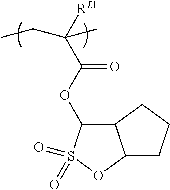

In the above formulae, R^{L1} represents a hydrogen atom, a fluorine atom, a methyl group, or a trifluoromethyl group.

The structural unit (IV) is preferably a structural unit that includes a lactone structure.

In the case in which the polymer (A) has the structural unit (IV), the lower limit of a proportion of the structural unit (IV) with respect to total structural units that constitute the polymer (A) is preferably 5 mol %, and more preferably 10 mol %. The upper limit of the proportion is preferably 40 mol %, and more preferably 30 mol %.

### Structural Unit (V)

The structural unit (V) is a structural unit that includes an alcoholic hydroxyl group. When the polymer (A) further has the structural unit (V), the solubility in a developer solution can be more appropriately adjusted. The polymer (A) can contain one, or two or more types of the structural unit (V).

The structural unit (V) is exemplified by structural units represented by the following formulae.

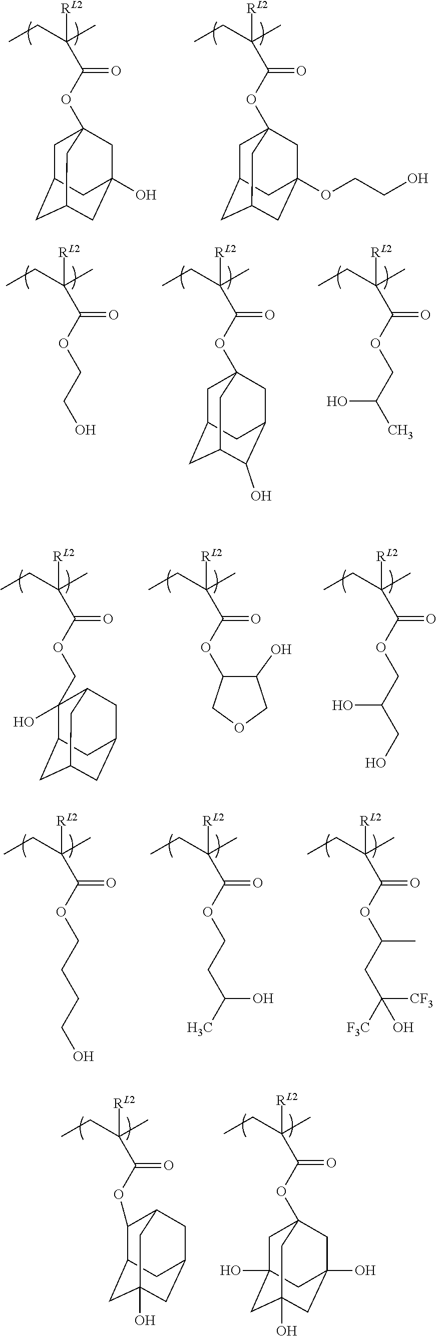

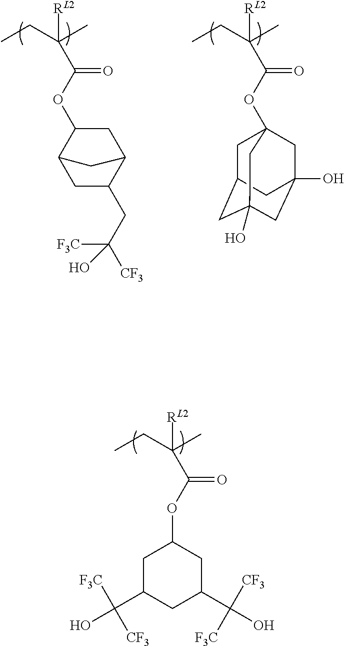

In the above formulae, R^{L2} represents a hydrogen atom, a fluorine atom, a methyl group, or a trifluoromethyl group.

In the case in which the polymer (A) has the structural unit (V), the lower limit of a proportion of the structural unit (V) with respect to total structural units constituting the polymer (A) is preferably 5 mol %, and more preferably 10 mol %. The upper limit of the proportion is preferably 40 mol %, and more preferably 30 mol %.

### (Z) Compound

The compound (Z) has: an anionic moiety (hereinafter, may be also referred to as “(X) anionic moiety” or “anionic moiety (X)”) including one type of anion group, and an aromatic ring in which at least one hydrogen atom is substituted with an iodine atom; and a radiation-sensitive onium cationic moiety (hereinafter, may be also referred to as “(Y) cationic moiety” or “cationic moiety (Y)”). The radiation-sensitive composition can contain one, or two or more types of the compound (Z).

Depending on the type of the anion group included in the anionic moiety (X), the compound (Z) has: a function of generating an acid in the radiation-sensitive composition upon an irradiation with a radioactive ray; or a function of inhibiting unwanted chemical reaction(s) (for example, a dissociation reaction of the acid-labile group) in light-unexposed regions through controlling a diffusion phenomenon, in the resist film, of the acid generated upon exposure, from the acid generating agent (B) described later, etc. In other words, depending on the type of the anion group, the compound (Z) serves as a radiation-sensitive acid generating agent or an acid diffusion control agent (quencher), in the radiation-sensitive composition.

In the case in which the compound (Z) serves as a radiation-sensitive acid generating agent, the acid generated from the compound (Z) upon an irradiation with a radioactive ray allows for dissociation of the acid-labile group (a) included in the structural unit (I) included in the polymer (A), etc., thereby generating a carboxy group or a phenolic hydroxyl group, whereby a difference in solubility of the resist film in the developer solution is generated between the light-exposed regions and the light-unexposed regions, and thus formation of the resist pattern is enabled.

In the case in which the compound (Z) serves as an acid diffusion control agent, an acid is generated in light-exposed regions to enhance solubility or insolubility of the polymer (A) in a developer solution, whereas in light-unexposed regions, the compound (Z) serves as a quencher through a superior acid-capturing function being exerted due to the anion, whereby the acid diffused from the light-exposed regions is captured. Accordingly, roughness at an interface between the light-exposed regions and the light-unexposed regions is improved, and the difference in the solubility in a developer solution between the light-exposed regions and the light-unexposed regions is increased, whereby the resolution can be improved.

Irrespective of the above function of the compound (Z) in the radiation-sensitive composition, the feature that the radiation-sensitive composition contains the compound (Z) is believed to be one factor for superior sensitivity and CDU exhibiting by the radiation-sensitive composition.

In the case in which the compound (Z) serves as a radiation-sensitive acid generating agent, the lower limit of a content of the compound (Z) in the radiation-sensitive composition, with respect to 100 parts by mass of the polymer (A), is preferably 1 part by mass, more preferably 5 parts by mass, and still more preferably 10 parts by mass. The upper limit of the content is preferably 70 parts by mass, more preferably 60 parts by mass, and still more preferably 50 parts by mass.

In the case in which the compound (Z) serves as an acid diffusion control agent, the lower limit of a proportion of the compound (Z) in the radiation-sensitive composition, with respect to the anionic moiety of the radiation-sensitive acid generating agent (the total of the compound (Z) that serves as a radiation-sensitive acid generating agent, and the acid generating agent (B), described later, which is used in combination as needed) accounting for 100 mol %, is preferably 20 mol %, more preferably 30 mol %, and still more preferably 40 mol %. The upper limit of the proportion is preferably 80 mol %, more preferably 70 mol %, and still more preferably 60 mol %.

Each structure included in the compound (Z) is described below.

### (X) Anionic Moiety

The anionic moiety (X) includes: one type of anion group (hereinafter, may be also referred to as “(x2) anion group” or “anion group (x2)”); and an aromatic ring (hereinafter, may be also referred to as “(x1) aromatic ring” or “aromatic ring (x1)”) in which at least one hydrogen atom is substituted with an iodine atom.

### (x1) Aromatic Ring

The aromatic ring (x1) is an aromatic ring in which at least one hydrogen atom is substituted with an iodine atom. The anionic moiety (X) can include one, or two or more types of the aromatic ring (x1).

The aromatic ring that gives the aromatic ring (x1) has at least one iodine atom bonded to the aromatic ring. In other words, at least one hydrogen atom bonding to an atom constituting the aromatic ring that gives the aromatic ring (x1) has been substituted with the iodine atom. The number of the substitution(s) with iodine atom(s) is not particularly limited as long as it is no less than 1. The number is, e.g., 1 to 5, and preferably 1 to 3. It is preferred that the number of the substitution(s) with iodine atom(s) is no less than 2 because the CDU tends to more improve, as compared with a case in which the number of the substitution(s) with iodine atom(s) is 1.

The number of ring atoms and the type of the aromatic ring that gives the aromatic ring (x1) are exemplified by those exemplified for the aromatic ring that gives Ar¹ in the above formula (1). The aromatic ring that gives the aromatic ring (x1) is preferably an aromatic hydrocarbon ring having 6 to 30 ring atoms, and more preferably a benzene ring.

The aromatic ring that gives the aromatic ring (x1) may further have at least one substituent, other than the iodine atom, bonded to the aromatic ring. The substituent is exemplified by those exemplified as the substituent that may be incorporated in the aromatic ring that gives Ar¹ in the above formula (1).

It is to be noted that the phrase “including an aromatic ring in which at least one hydrogen atom is substituted with an iodine atom” as referred to herein encompasses not only a case of including one aromatic ring in which at least one hydrogen atom is substituted with an iodine atom, but also a case in which two or more aromatic rings in each of which at least one hydrogen atom is substituted with an iodine atom are included, and the aromatic rings are bonded to each other via a linking group.

The “linking group” as referred to herein means a group that links two or more structures. The linking group remains in the structure of a compound due to a reason such as a synthesis material or a synthesis procedure, and does not influence the effects of the present invention or has an extremely small influence on the effects of the present invention. It is to be noted that this does not mean that all the structures aside from the linking group contribute to an exhibition of the effects of the present invention. The linking group is not particularly limited as long as it is a group that links two or more structures. The linking group is exemplified by: a carbonyl group; an ether group; a carbonyloxy group; a sulfide group; an alkanediyl group having 1 to 10 carbon atoms; or a group obtained by combining the same.

### (x2) Anion Group

The anion group (x2) is one type of anion group. The phrase “including one type of anion group” as referred to herein literally means that the anionic moiety (X) includes one type of anion group. As long as the type of anion group(s) is one type, the number of the anion group(s) (i.e., the valency of the anionic moiety) may be any number. The valency of the anionic moiety (X) is, for example, monovalent to trivalent, preferably monovalent or divalent, and more preferably monovalent.

The type of the anion group (x2) is not limited as long as it is well-known as an anion group of a radiation-sensitive acid generating agent or as an anion group of an acid diffusion control agent. The anion group (x2) is exemplified by a sulfonic acid anion group (—SO₃⁻) and a carboxylic acid anion group (—COO⁻).

In the case in which the anion group (x2) is a sulfonic acid anion group, the compound (Z) may serve as a radiation-sensitive acid generating agent in the radiation-sensitive composition. In this case, the radiation-sensitive composition preferably contains an acid diffusion control agent. The acid diffusion control agent may be the compound (Z) that serves as an acid diffusion control agent, or may be an acid diffusion control agent other than the compound (Z) (the acid diffusion control agent (C)). It is preferred that the radiation-sensitive composition further contains the compound (Z) that serves as an acid diffusion control agent, in addition to the compound (Z) that serves as a radiation-sensitive acid generating agent because the sensitivity and the inhibitory ability of development defects tend to more improve.

In the case in which the anion group (x2) is a carboxylic acid anion group, the compound (Z) may serve as an acid diffusion control agent in the radiation-sensitive composition. In this case, the radiation-sensitive composition typically contains a radiation-sensitive acid generating agent. The radiation-sensitive acid generating agent may be the compound (Z) that serves as a radiation-sensitive acid generating agent, or may be a radiation-sensitive acid generating agent (the acid generating agent (B)) other than the compound (Z).

The radiation-sensitive composition preferably contains, as the compound (Z), at least the compound (Z) that serves as a radiation-sensitive acid generating agent. In this case, more improving the CDU tends to be enabled, as compared with a case in which the radiation-sensitive composition contains, as the compound (Z), only the compound (Z) that serves as an acid diffusion control agent.

The aromatic ring (x1) and the anion group (x2) may directly bond to each other, or may bond via a partial structure (hereinafter, may be also referred to as “(x3) partial structure” or “partial structure (x3)”).

### (x3) Partial Structure

The partial structure (x3) is exemplified by a group represented by the following formula (x3) and having a valency of (n+1).

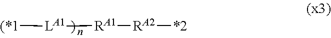

In the above formula (x3), R^{A1} represents a single bond or a group obtained by removing (n+1) hydrogen atoms from a ring structure; n is an integer of 1 to 5; R^{A2} represents a single bond or a substituted or unsubstituted divalent hydrocarbon group having 1 to 20 carbon atoms; L^{A1} represents a single bond or a linking group, wherein in the case in which n is no less than 2, a plurality of L^{A1}s are the same or different; * 1 denotes a site bonding to the aromatic ring (x1); and *2 denotes a site bonding to the anion group (x2), wherein a case in which R^{A1}, R^{A2}, and L^{A1} each represent a single bond is excluded.

The ring structure that gives R^{A1} has, e.g., 3 to 30 ring atoms, and preferably 6 to 20 ring atoms.

The ring structure that gives R^{A1} is exemplified by the above-described alicyclic rings, aromatic rings, or a combination thereof. The ring structure that gives R^{A1} is preferably a ring obtained by combining an aliphatic hydrocarbon ring with an aliphatic heterocyclic ring, or an aromatic hydrocarbon ring, and more preferably 3,5-dioxatricyclo[5.2.1.0^{2,6}]decane or a benzene ring.

The substituted or unsubstituted divalent hydrocarbon group having 1 to 20 carbon atoms, which may be represented by R^{A2}, is preferably a divalent fluorinated hydrocarbon group having 1 to 20 carbon atoms. The divalent fluorinated hydrocarbon group having 1 to 20 carbon atoms is obtained by substituting a fluorine atom for at least one hydrogen atom included in a divalent hydrocarbon group having 1 to 20 carbon atoms. The divalent hydrocarbon group having 1 to 20 carbon atoms is exemplified by a group obtained by removing one hydrogen atom from the above-described monovalent hydrocarbon group having 1 to 20 carbon atoms.

The number of the substitution(s) with fluorine atom(s) in the divalent fluorinated hydrocarbon group is, for example, 1 to 10, and preferably 2 to 6. It is preferred that the number of the substitution(s) with fluorine atom(s) is no less than 3 because the CDU of the radiation-sensitive composition tends to more improve.

In the case in which the anion group (x2) is a sulfonic acid anion group, R^{A2} preferably represents a divalent fluorinated hydrocarbon group having 1 to 20 carbon atoms.

The divalent fluorinated hydrocarbon group having 1 to 20 carbon atoms, which may be represented by R^{A2}, is preferably a fluorinated alkanediyl group or a fluorinated arylene group. The fluorinated alkanediyl group is preferred because the CDU of the radiation-sensitive composition tends to more improve.

The linking group that may be represented by L^{A1} is exemplified by those exemplified in the above section of “(x1) Aromatic Ring”.

n is preferably 1 or 2, and more preferably 1.

A case in which R^{A1}, R^{A2}, and L^{A1} each represent a single bond is excluded. The reason is that in this case, the partial structure (x3) as a whole is a single bond, and this case corresponds to the above-described case in which the aromatic ring (x1) and the anion group (x2) directly bond.

The partial structure (x3) is preferably a divalent group represented by any one of the following formulae (x3-1) to (x3-11).

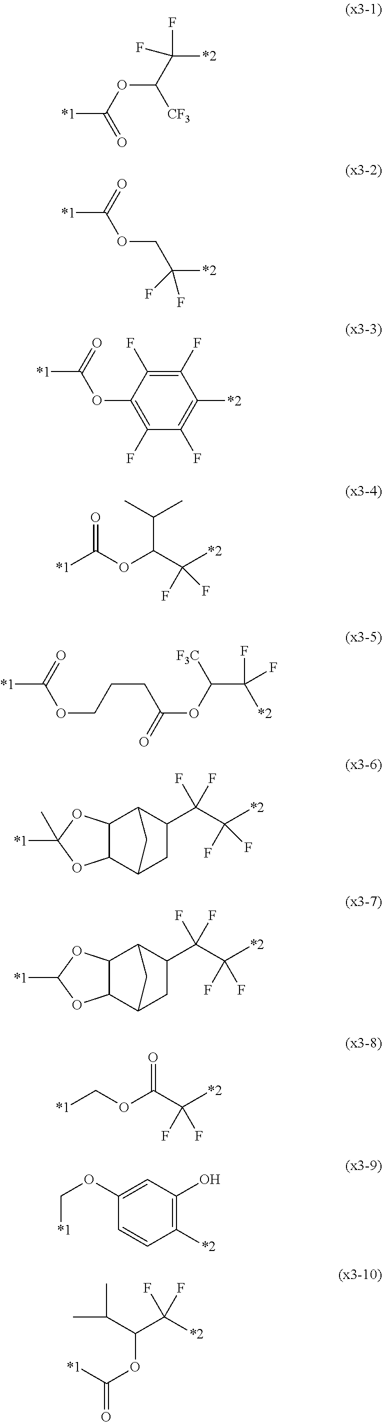

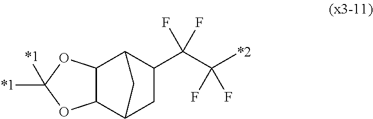

In the above formulae (x3-1) to (x3-11), *1 and *2 are as defined in the above formula (x3).

### (Y) Cationic Moiety

The cationic moiety (Y) is a radiation-sensitive onium cation. The valency of the cationic moiety (Y) can be appropriately determined depending on the valency of the anionic moiety (X), and is, for example, monovalent to trivalent, and is preferably monovalent. It is to be noted that, for example, in the case in which the anionic moiety (Y) is a divalent or higher anion and the cationic moiety (X) is a monovalent cation, the compound (Z) has one anionic moiety and two cationic moieties.

In the case in which the cationic moiety (Y) is a monovalent cation, the cation species thereof is exemplified by a sulfonium cation (S⁺) and an iodonium cation (I⁺).

The cationic moiety (Y) preferably includes an aromatic ring (hereinafter, may be also referred to as “aromatic ring (y1)”) having at least one fluorine atom or at least one fluorine atom-containing group bonded to the aromatic ring. In this case, more enhancing the sensitivity of the radiation-sensitive composition tends to be enabled. The cationic moiety (Y) can contain one, or two or more of the aromatic ring (y1).

The aromatic ring that gives the aromatic ring (y1) has at least one fluorine atom or at least one fluorine atom-containing group bonded to the aromatic ring. In other words, at least one hydrogen atom bonding to an atom constituting the aromatic ring that gives the aromatic ring (y1) has been substituted with a fluorine atom or a fluorine atom-containing group. The number of the substitution(s) with fluorine atom(s) or fluorine atom-containing group(s) is not particularly limited as long as it is no less than 1. The number is, e.g., 1 to 10. A case in which the total of the fluorine atom(s) bonding to the aromatic ring (y1) and the fluorine atom(s) in the fluorine atom-containing group bonding to the aromatic ring (y1) in the entire cationic moiety (Y) is no less than 4 is preferred because the sensitivity of the radiation-sensitive composition tends to further improve, as compared with a case in which the total of the fluorine atoms is no greater than 3.

The number of ring atoms and the type of the aromatic ring that gives the aromatic ring (y1) are exemplified by those exemplified for the aromatic ring that give Ar¹ in the above formula (1). The aromatic ring that gives the aromatic ring (y1) is preferably an aromatic hydrocarbon ring having 6 to 30 ring atoms or an aromatic heterocyclic ring having 5 to 30 ring atoms, more preferably a benzene ring, a condensed polycyclic aromatic hydrocarbon ring, or a sulfur atom-containing aromatic heterocyclic ring, and still more preferably a benzene ring, a naphthalene ring, or a dibenzothiophene ring.

The “fluorine atom-containing group” as referred to herein means a group having at least one fluorine atom. The fluorine atom-containing group is exemplified by the above-described fluorinated hydrocarbon groups. The fluorine atom-containing group is preferably a fluorinated alkyl group, and more preferably a trifluoromethyl group.

The aromatic ring that gives the aromatic ring (y1) may further have at least one substituent, other than the fluorine atom and the fluorine atom-containing group, bonded to the aromatic ring. The substituent is exemplified by: halogen atoms other than a fluorine atom; a hydroxy group; a carboxy group; a cyano group; a nitro group; an alkyl group; an alkoxy group; an alkoxycarbonyl group; an alkoxycarbonyloxy group; an acyl group; an acyloxy group; and an oxo group (═O).

The cationic moiety (Y) is exemplified by a monovalent cation represented by the following formula (r-a).

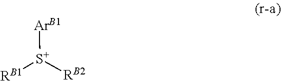

In the above formula (r-a), Ar^{B1} represents a group obtained by removing one hydrogen atom from a substituted or unsubstituted aromatic hydrocarbon ring having 6 to 20 ring atoms; and R^{B1} and R^{B2} each independently represent a group obtained by removing one hydrogen atom from a substituted or unsubstituted aromatic hydrocarbon ring having 6 to 20 ring atoms, or R^{B1} and R^{B2} taken together represent a substituted or unsubstituted polycyclic sulfur atom-containing aromatic heterocyclic ring having 9 to 30 ring atoms, together with the sulfur atom to which R^{B1} and R^{B2} bond.

The aromatic hydrocarbon ring having 6 to 20 ring atoms that gives Ar^{B1}, R^{B1}, or R^{B2} is described as a preferred mode of the above aromatic ring (y1). The polycyclic sulfur atom-containing aromatic heterocyclic ring having 9 to 30 ring atoms, which may be represented by R^{B1} and R^{B2} taken together, together with the sulfur atom to which R^{B1} and R^{B2} bond is also described as a preferred mode of the above aromatic ring (y1).

The cationic moiety (Y) is preferably a monovalent cation represented by any one of the following formulae (r-a-1) to (r-a-10).

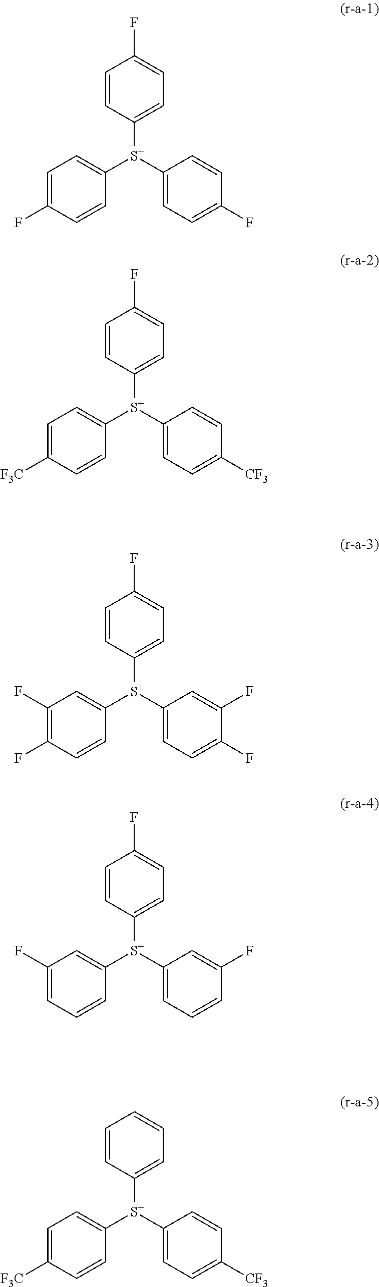 [SMILES: Fc1ccc([S+](c2ccc(F)cc2)c2ccc(F)cc2)cc1 ; Fc1ccc([S+](c2ccc(C(F)(F)F)cc2)c2ccc(C(F)(F)F)cc2)cc1 ; Fc1ccc([S+](c2ccc(F)c(F)c2)c2ccc(F)c(F)c2)cc1 ; Fc1ccc([S+](c2cccc(F)c2)c2cccc(F)c2)cc1 ; FC(F)(F)c1ccc([S+](c2ccccc2)c2ccc(C(F)(F)F)cc2)cc1]

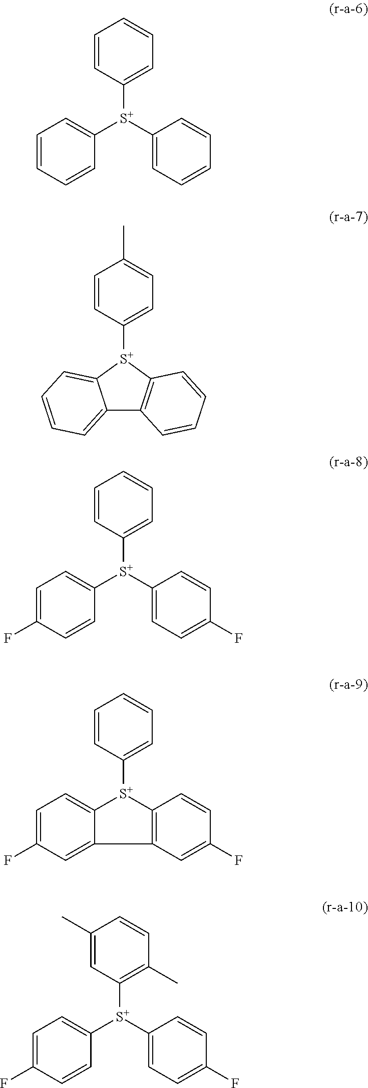 [SMILES: c1ccc([S+](c2ccccc2)c2ccccc2)cc1 ; Cc1ccc(-[s+]2c3ccccc3c3ccccc32)cc1 ; Fc1ccc([S+](c2ccccc2)c2ccc(F)cc2)cc1 ; Fc1ccc2c(c1)c1cc(F)ccc1[s+]2-c1ccccc1 ; Cc1ccc(C)c([S+](c2ccc(F)cc2)c2ccc(F)cc2)c1]

As the compound (Z), a compound obtained by appropriately combining the above-described anionic moiety (X) and the above-described cationic moiety (Y) can be 5 used.

### (B) Acid Generating Agent

The acid generating agent (B) is a radiation-sensitive acid generating agent other than the compound (Z). The acid generating agent (B) is a compound that generates an acid upon an irradiation with a radioactive ray. In the case in which the compound (Z) contained in the radiation-sensitive composition serves as an acid diffusion control agent, the radiation-sensitive composition typically contains the acid generating agent (B). In this case, the acid generated from the acid generating agent (B) upon an irradiation with a radioactive ray allows for dissociation of the acid-labile group (a) included in the structural unit (I) of the polymer (A), etc., thereby generating a carboxy group, a phenolic hydroxyl group, etc., whereby a difference in solubility of the resist film in the developer solution is generated between the light-exposed regions and the light-unexposed regions, and thus formation of the resist pattern is enabled. The radiation-sensitive composition can contain one, or two or more types of the acid generating agent (B).

As the acid generating agent (B), any compound that does not correspond to the compound (Z) and can be used as a radiation-sensitive acid generating agent can be used without any particular limitation. The acid generating agent (B) is exemplified by an onium salt compound, an N-sulfonyloxyimide compound, a sulfonimide compound, a halogen-containing compound, and a diazoketone compound. Furthermore, specific examples of the acid generating agent (B) include compounds disclosed in paragraphs 0080 to 0113 of Japanese Unexamined Patent Application, Publication No. 2009-134088.

The acid generating agent (B) is preferably an onium salt compound, more preferably a compound having a radiation-sensitive onium cationic moiety and an anionic moiety of a strong acid, and still more preferably a compound having a radiation-sensitive onium cationic moiety and a sulfonic acid anionic moiety. In other words, the acid generating agent (B) is more preferably a compound that generates a strong acid upon exposure, and still more preferably a compound that generates a sulfonic acid upon exposure.

The radiation-sensitive onium cation is exemplified by those exemplified as the monovalent radiation-sensitive onium cation in the above section of “(Z) Compound”.

The anionic moiety of a strong acid is exemplified by those containing a sulfonic acid anion group as an anion group, and the like.

The anionic moiety of a strong acid preferably further has a ring structure. The ring structure is exemplified by ring structures having 5 or more ring atoms, among the above-described ring structures. The ring structure may have 6 to 30 ring atoms, for example.

The acid generating agent (B) that may be used is a compound obtained by appropriately combining the above-described radiation-sensitive onium cationic moiety and the above-described anionic moiety of a strong acid. The acid generating agent (B) is exemplified by acid generating agents (B-10) to (B-12) in the Examples described later.

In the case in which the radiation-sensitive composition contains the acid generating agent (B), the lower limit of a content of the acid generating agent (B) in the radiation-sensitive composition, with respect to 100 parts by mass of the polymer (A), is preferably 1 part by mass, more preferably 5 parts by mass, and still more preferably 10 parts by mass. The upper limit of the content is preferably 70 parts by mass, more preferably 60 parts by mass, and still more preferably 50 parts by mass.

### (C) Acid Diffusion Control Agent

The acid diffusion control agent (C) is an acid diffusion control agent other than the compound (Z). In particular, in the case in which the compound (Z) contained in the radiation-sensitive composition serves as a radiation-sensitive acid generating agent, the radiation-sensitive composition preferably contains the acid diffusion control agent (C). In this case, the acid diffusion control agent (C) controls a diffusion phenomenon, in the resist film, of the acid generated, upon exposure, from the compound (Z) and the acid generating agent (B) used in combination as needed, thereby serving to control unwanted chemical reactions in the light-unexposed regions. The radiation-sensitive composition can contain one, or two or more types of the acid diffusion control agent (C).

The acid diffusion control agent (C) is exemplified by: nitrogen atom-containing compounds; compounds that generate a weak acid upon exposure (hereinafter, may be also referred to as “photodegradable base”); and the like. The acid diffusion control agent (C) is preferably the photodegradable base.

Examples of the nitrogen atom-containing compound include: amine compounds such as tripentylamine and trioctylamine; amide group-containing compounds such as formamide and N,N-dimethylacetamide; urea compounds such as urea and 1,1-dimethylurea; nitrogen-containing heterocyclic compounds such as pyridine, N-(undecylcarbonyloxyethyl) morpholine, and N-t-pentyloxycarbonyl-4-hydroxypiperidine; and the like.

The photodegradable base is exemplified by: a compound containing a radiation-sensitive onium cationic moiety and an anionic moiety of a weak acid; and the like. The photodegradable base generates a weak acid in light-exposed regions and enhances the solubility or insolubility of the polymer (A) in a developer solution, and consequently roughness of surfaces of the light-exposed regions after the development is reduced. On the other hand, the photodegradable base exerts a superior acid-capturing function due to an anion in light-unexposed regions and serves as a quencher, and thus captures the acid diffused from the light-exposed regions. In other words, since the photodegradable base serves as a quencher only at the light-unexposed regions, the contrast resulting from an elimination reaction of an acid-labile group is improved, and consequently the resolution can be improved. Due to generating an acid upon exposure, the photodegradable base may be also referred to as a radiation-sensitive acid generating agent in a broad sense; however, under conditions in which the acid generated from the acid generating agent (B) upon exposure allows for dissociation of an acid-labile group, the photodegradable base does not cause dissociation of the acid-labile group upon exposure, and thus is clearly distinguished from the radiation-sensitive acid generating agent.

The radiation-sensitive onium cationic moiety is exemplified by those similar to those exemplified as the monovalent radiation-sensitive onium cation in the section of “(Z) Compound”.

The above-described anionic moiety of a weak acid is exemplified by those each including a carboxylic acid anion group as an anion group.

The anionic moiety of a weak acid is, e.g., preferably a carboxylic acid anion represented by any one of the following formulae (Q-1) to (Q-5).

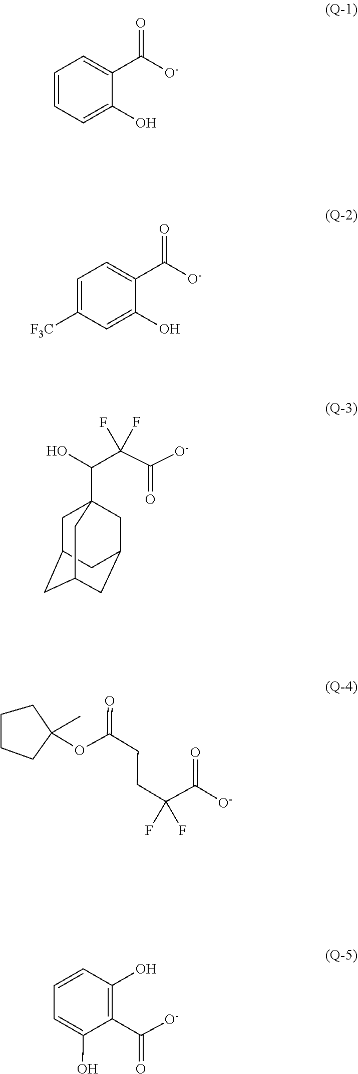 [SMILES: O=C([O-])c1ccccc1O ; O=C([O-])c1ccc(C(F)(F)F)cc1O ; O=C([O-])C(F)(F)C(O)C12CC3CC(CC(C3)C1)C2 ; CC1(OC(=O)CCC(F)(F)C(=O)[O-])CCCC1 ; O=C([O-])c1c(O)cccc1O]

The photodegradable base that may be used is a compound obtained by appropriately combining the above-described radiation-sensitive onium cationic moiety and the above-described anionic moiety of a weak acid.

In the case in which the radiation-sensitive composition contains the acid diffusion control agent (C), the lower limit of a proportion of the acid diffusion control agent (C) in the radiation-sensitive composition, with respect to the anionic moiety of the radiation-sensitive acid generating agent (the compound (Z) that serves as a radiation-sensitive acid generating agent and/or the acid generating agent (B)) accounting for 100 mol %, is preferably 20 mol %, more preferably 30 mol %, and still more preferably 40 mol %. The upper limit of the proportion is preferably 200 mol %, more preferably 120 mol %, and still more preferably 80 mol %.

### (D) Organic Solvent

The radiation-sensitive composition typically contains the organic solvent (D). The organic solvent (D) is not particularly limited as long as it is a solvent capable of dissolving or dispersing at least the polymer (A) and the compound (Z), as well as the acid generating agent (B), the acid diffusion control agent (C), and the other optional component(s), which is/are contained as needed.

The organic solvent (D) is exemplified by an alcohol solvent, an ether solvent, a ketone solvent, an amide solvent, an ester solvent, and a hydrocarbon solvent. The radiation-sensitive composition can contain one, or two or more types of the organic solvent (D).

### Examples of the Alcohol Solvent Include:

aliphatic monohydric alcohol solvents such as 4-methyl-2-pentanol, n-hexanol, and diacetone alcohol;
alicyclic monohydric alcohol solvents such as cyclohexanol;
polyhydric alcohol solvents such as 1,2-propylene glycol; and
polyhydric alcohol partial ether solvents such as propylene glycol monomethyl ether.

### Examples of the Ether Solvent Include:

dialkyl ether solvents such as diethyl ether, dipropyl ether, dibutyl ether, dipentyl ether, diisoamyl ether, dihexyl ether, and diheptyl ether;
cyclic ether solvents such as tetrahydrofuran and tetrahydropyran; and
aromatic ring-containing ether solvents such as diphenyl ether and anisole.

### Examples of the Ketone Solvent Include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone, and trimethylnonanone;
cyclic ketone solvents such as cyclopentenone, cyclohexanone, cycloheptanone, cyclooctanone, and methylcyclohexanone; and 2,4-pentanedione, acetonylacetone, and acetophenone.

### Examples of the Amide Solvent Include:

cyclic amide solvents such as N,N′-dimethylimidazolidinone and N-methylpyrrolidone; and
chain amide solvents such as N-methylformamide, N,N-dimethylformamide, N,N-diethylformamide, acetamide, N-methylacetamide, N,N-dimethylacetamide, and N-methylpropionamide.

### Examples of the Ester Solvent Include:

monocarboxylic acid ester solvents such as n-butyl acetate and ethyl lactate;
lactone solvents such as γ-butyrolactone and valerolactone;
polyhydric alcohol carboxylate solvents such as propylene glycol acetate;
polyhydric alcohol partial ether carboxylate solvents such as propylene glycol monomethyl ether acetate;
polyhydric carboxylic acid diester solvents such as diethyl oxalate; and
carbonate solvents such as dimethyl carbonate and diethyl carbonate.

### Examples of the Hydrocarbon Solvent Include:

aliphatic hydrocarbon solvents such as n-pentane and n-hexane; and
aromatic hydrocarbon solvents such as toluene and xylene.

The organic solvent (D) is preferably the alcohol solvent, the ester solvent, or a combination of the same, more preferably the polyhydric alcohol partial ether solvent, the polyhydric alcohol partial ether carboxylate solvent, or a combination of the same, and still more preferably propylene glycol monomethyl ether, propylene glycol monomethyl ether acetate, or a combination of the same.

In the case of the radiation-sensitive composition containing the organic solvent (D), the lower limit of a proportion of the organic solvent (D) with respect to total components contained in the radiation-sensitive composition is preferably 50% by mass, more preferably 60% by mass, still more preferably 70% by mass, and particularly preferably 80% by mass. The upper limit of the proportion is preferably 99.9% by mass, more preferably 99.5% by mass, and still more preferably 99.0% by mass.

### (F) Polymer

The polymer (F) is a polymer that differs from the polymer (A), and has a percentage content of fluorine atoms which is greater than that of the polymer (A). In general, a more hydrophobic polymer than a polymer that serves as a base polymer tends to be localized in a resist film surface layer. Since the polymer (F) has a percentage content of fluorine atoms which is greater than that of the polymer (A), due to characteristics resulting from the hydrophobicity, the polymer (F) tends to be localized in the resist film surface layer. As a result, in the case in which the radiation-sensitive composition contains the polymer (F), a cross-sectional shape of a resist pattern to be formed is expected to be favorable. The radiation-sensitive composition may contain the polymer (F) as, for example, a surface conditioning agent of a resist film. The radiation-sensitive composition may contain one, or two or more types of the polymer (F).

### Other Optional Component(s)

The other optional component(s) is/are exemplified by a surfactant and the like. The radiation-sensitive composition can contain one, or two or more types of the other optional component(s).

Alternatively, the radiation-sensitive composition may be a radiation-sensitive composition containing a polymer (hereinafter, may be also referred to as “(A2) polymer” or “polymer (A2)”) having:
a structural unit including a partial structure obtained by substituting a hydrogen atom of a carboxy group or a hydrogen atom of a phenolic hydroxyl group, with an acid-labile group represented by the above formula (1); and
a structural unit including: an anionic moiety including one type of anion group, and an aromatic ring in which at least one hydrogen atom is substituted with an iodine atom; and a radiation-sensitive onium cationic moiety.

The structural unit including a partial structure obtained by substituting a hydrogen atom of a carboxy group or a hydrogen atom of a phenolic hydroxyl group, with an acid-labile group represented by the above formula (1) is the structural unit (I) described in the above section of “(A) Polymer”.

The structural unit including: an anionic moiety including one type of anion group, and an aromatic ring in which at least one hydrogen atom is substituted with an iodine atom; and a radiation-sensitive onium cationic moiety is the structural unit including the anionic moiety (X) and the cationic moiety (Y) as described in the above section of “(Z) Compound”. Such a structural unit is a structural unit that generates an acid corresponding to the anion group included in the anionic moiety (X) due to an action of a radioactive ray. Thus, depending on the type of the anion group included in the anionic moiety (X), the polymer (A2) serves as a radiation-sensitive acid generating agent or an acid diffusion control agent (quencher) in the radiation-sensitive composition.

### Method of Forming Resist Pattern

The method of forming a resist pattern includes: a step (hereinafter, may be also referred to as “applying step”) of applying a radiation-sensitive composition directly or indirectly on a substrate to form a resist film; a step (hereinafter, may be also referred to as “exposing step”) of exposing the resist film; and a step (hereinafter, may be also referred to as “developing step”) of developing the resist film exposed.

In the applying step, the above-described radiation-sensitive composition is used as the radiation-sensitive composition. Therefore, the method of forming a resist pattern enables forming a resist pattern that has favorable sensitivity and superior CDU, and in which occurrence of development defects is inhibited.

Each step included in the method of forming a resist pattern is described below.

### Applying Step

In this step, the radiation-sensitive composition is applied directly or indirectly on a substrate. By this step, a resist film is formed directly or indirectly on the substrate.

In this step, the above-described radiation-sensitive composition is used as the radiation-sensitive composition.

The substrate is exemplified by conventionally well-known substrates such as a silicon wafer, and a wafer coated with silicon dioxide or aluminum.

The application procedure is exemplified by spin coating, cast coating, roll coating, and the like. After the application, prebaking (hereinafter, may be also referred to as “PB”) may be carried out as needed for evaporating the solvent remaining in the coating film. A PB temperature and a PB time period are not particularly limited, and the PB is performed, for example, at a temperature of 60° C. or higher and 150° C. or lower for a time period of no less than 5 sec and no greater than 300 sec. An average thickness of the resist film formed is not particularly limited, and is, e.g., no less than 10 nm and no greater than 1,000 nm.

### Exposing Step

In this step, the resist film formed by the applying step is exposed. This exposure is carried out by irradiation with an exposure light through a photomask (as the case may be, through a liquid immersion medium such as water). As the exposure light, far ultraviolet rays, EUV, or electron beams are preferred; an ArF excimer laser beam (wavelength: 193 nm), a KrF excimer laser beam (wavelength: 248 nm), EUV (wavelength: 13.5 nm), or an electron beam is more preferred; a KrF excimer laser beam, EUV, or an electron beam is still more preferred; and EUV or an electron beam is particularly preferred.

It is preferred that post exposure baking (hereinafter, may be also referred to as “PEB”) is carried out after the exposure. This PEB enables increasing a difference in solubility in a developer solution between light-exposed regions and light-unexposed regions. A PEB temperature and a PEB time period are not particularly limited, and the PEB can be performed, for example, at a temperature of 50° C. or higher and 180° C. or lower for a time period of no less than 5 sec and no greater than 600 sec.

### Developing Step

In this step, the resist film exposed is developed. Accordingly, formation of a predetermined resist pattern is enabled. The development procedure in the developing step may be carried out by either development with an alkali, or development with an organic solvent.

In the case of the development with an alkali, the developer solution for use in the development is exemplified by: alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (hereinafter, may be also referred to as “TMAH”), pyrrole, piperidine, choline, 1,8-diazabicyclo-[5.4.0]-7-undecene, and 1,5-diazabicyclo-[4.3.0]-5-nonene. Of these, an aqueous TMAH solution is preferred, and a 2.38% by mass aqueous TMAH solution is more preferred.

In the case of the development with an organic solvent, the developer solution is exemplified by the organic solvents exemplified as the organic solvent (D) in the above-described radiation-sensitive composition.

### EXAMPLES

Hereinafter, the present invention is explained in detail by way of Examples, but the present invention is not in any way limited to these Examples. Measuring methods for various types of physical property values are shown below.

Weight Average Molecular Weight (Mw), Number Average Molecular Weight (Mn), and Polydispersity Index (Mw/Mn)

Measurements of the Mw and the Mn of the polymer were carried out in accordance with the conditions described in the above section of “Method for Measuring Mw and Mn”. The polydispersity index (Mw/Mn) of the polymer was calculated from the measurement results of the Mw and the Mn.

### Synthesis of Monomer (X)

According to the following procedure, compounds (hereinafter, may be also referred to as “monomers (X-1) to (X-12)”) represented by the following formulae (X-1) to (X-12) as the monomer (X) were synthesized.

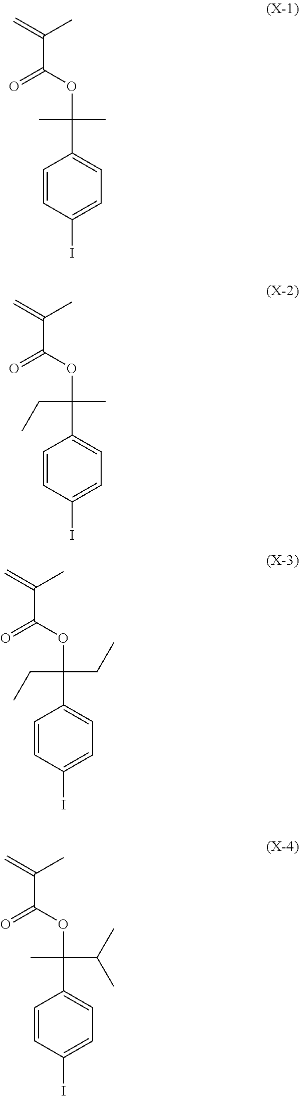

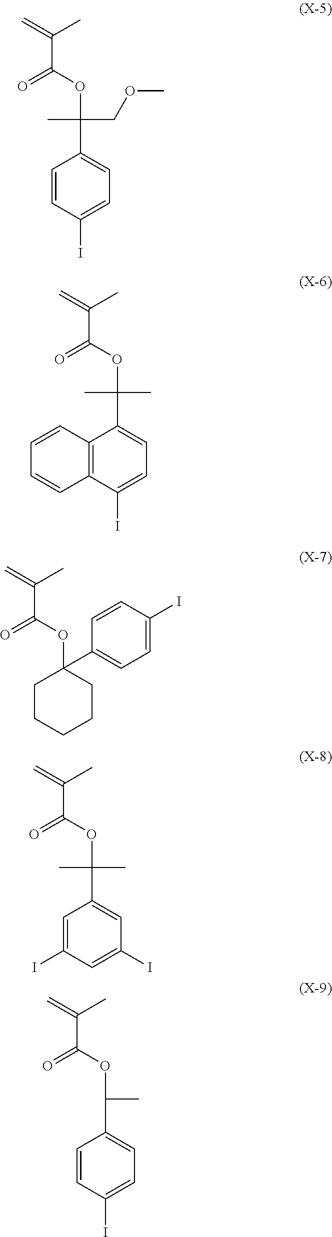

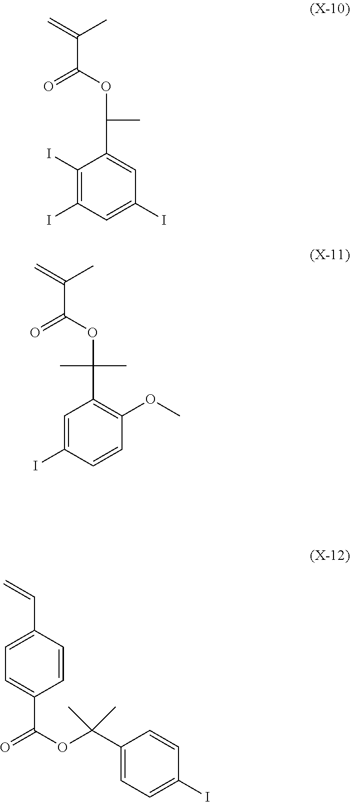 [SMILES: C=C(C)C(=O)OC(C)c1cc(I)cc(I)c1I ; C=C(C)C(=O)OC(C)(C)c1cc(I)ccc1OC ; C=Cc1ccc(C(=O)OC(C)(C)c2ccc(I)cc2)cc1]

### Synthesis Example 1-1: Synthesis of Monomer (X-1)

Into a vessel containing tetrahydrofuran (300 mL) was charged a compound (P-1) (150 mmol), and a thus resulting mixture was cooled to 0° C. Into this vessel, 180 mL of a 1 mol/L solution of methylmagnesium bromide in tetrahydrofuran was added dropwise. Stirring was conducted for 8 hours at room temperature. After cooling to 0° C., an aqueous ammonium chloride solution and ethyl acetate were added thereto. An organic layer was washed with a saline solution, and then ultra-pure water, in this order. The organic layer was dried over sodium sulfate and then filtered off. A solvent was distilled away to give a compound (P-2).

Into a vessel containing acetonitrile (150 mL) were charged the compound (P-2) (150 mmol) and triethylamine (180 mmol), and a thus resulting mixture was cooled to 0° C. Into this vessel, methacryloyl chloride (180 mmol) was added dropwise. Stirring was conducted for 3 hours at room temperature, and then an aqueous ammonium chloride solution, and ethyl acetate were added thereto. An organic layer was washed with a saline solution, and then ultra-pure water, in this order. The organic layer was dried over sodium sulfate and then filtered off. A solvent was distilled away to give a monomer (X-1).

A synthesis scheme of the monomer (X-1) is shown below. In the following synthesis scheme, NEt₃ represents triethylamine.

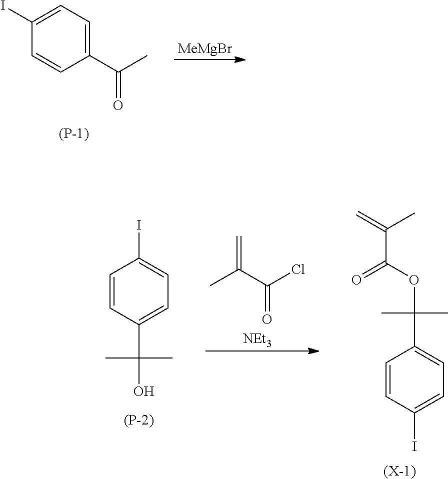

### Synthesis Examples 1-2 to 1-12: Syntheses of Monomers (X-2) to (X-12)

Monomers (X-2) to (X-12) were synthesized in a similar manner to Synthesis Example 1-1 except that the precursor was appropriately selected.

### Synthesis of Polymer (A)

According to the following procedure, polymers (A-1) to (A-30), (CA-1), and (CA-2) to serve as the polymer (A) were synthesized. For synthesis of the polymer (A), the monomers (X-1) to (X-12), and compounds (hereinafter, may be also referred to as “monomers (M-1) to (M-16), (CX-1), and (CX-2)”) represented by the following formulae (M-1) to (M-16), (CX-1), and (CX-2) were used. In the following Synthesis Examples, unless otherwise specified particularly, the term “parts by mass” means a value, provided that the total mass of the monomers used was 100 parts by mass, and the term “mol %” means a value, provided that the total mol number of the monomers used was 100 mol %.

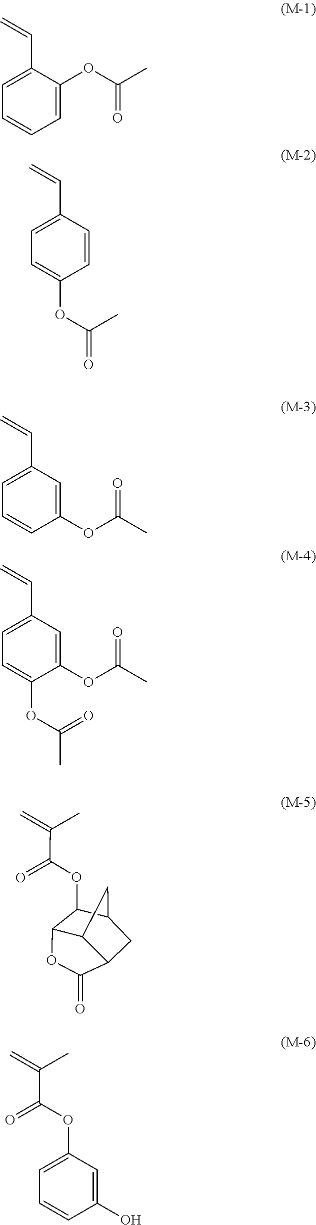

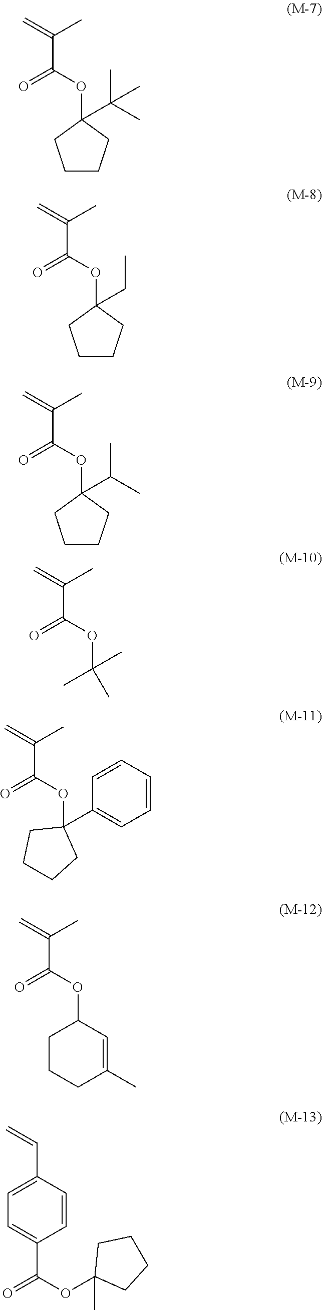

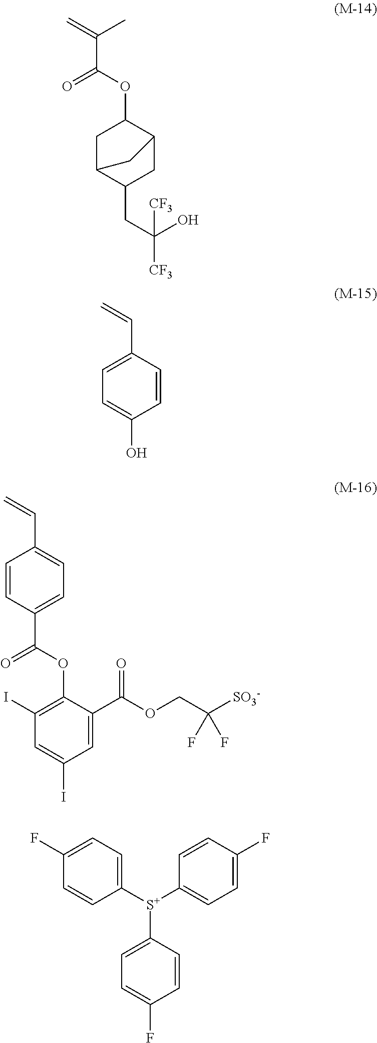

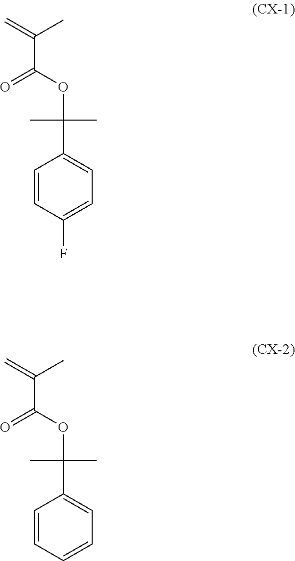 [SMILES: C=C(C)C(=O)OC(C)(C)c1ccc(F)cc1 ; C=C(C)C(=O)OC(C)(C)c1ccccc1]

### Synthesis Example 2-1: Synthesis of Polymer (A-1)

The monomer (X-1), the monomer (M-2), and the monomer (M-8) were dissolved in propylene glycol monomethyl ether (200 parts by mass) such that a molar ratio of the monomers became 20/45/35. Next, thereto was added as an initiator, azobis(methylisobutyrate) (10 mol %) to prepare a monomer solution. Propylene glycol monomethyl ether (100 parts by mass) was charged into an empty reaction vessel, and was heated to 85° C. with stirring. Next, the monomer solution prepared as described above was added dropwise over 3 hours, and then a thus resulting solution was further heated for 3 hours at 85° C. After completion of the polymerization reaction, the polymerization solution was cooled to room temperature. The polymerization solution thus cooled was charged into n-hexane (1,000 parts by mass) to allow for solidification purification of the polymer. To the polymer thus recovered were added propylene glycol monomethyl ether (150 parts by mass), methanol (150 parts by mass), triethylamine (1.5 molar equivalent with respect to the using amount of the monomer (M-2)), and water (1.5 molar equivalent with respect to the using amount of the monomer (M-2)). A hydrolysis reaction was performed for 8 hours while reflux was allowed at a boiling point. After completion of the reaction, the solvent and the triethylamine were distilled away under reduced pressure, and a polymer thus obtained was dissolved in acetone (150 parts by mass). This solution was added dropwise into water (2,000 parts by mass) to permit coagulation, and white powder thus generated was filtered off. Drying at 50° C. for 17 hours gave a white powdery polymer (A-1) with a favorable yield. The Mw of the polymer (A-1) was 5,900, and the Mw/Mn was 1.5.

### Synthesis Examples 2-2 to 2-31: Synthesis of Polymers (A-2) to (A-29), (CA-1), and (CA-2)

Polymers (A-2) to (A-29), (CA-1), and (CA-2) were synthesized in a similar manner to Synthesis Example 2-1 except that monomers of the type and the using amount shown in Table 1 below were used.

### Synthesis Example 2-32: Synthesis of Polymer (A-30)

In a similar manner to Synthesis Example 2-1 except that the step of hydrolysis with triethylamine was not performed in Synthesis Example 2-1, each monomer was combined and a copolymerization reaction thereof was allowed to proceed in the presence of a tetrahydrofuran (THF) solvent, followed by isolation and drying, to give a base polymer (A-30) having a constitution as shown below. The constitution of the base polymer obtained was confirmed by 1H-NMR, and the Mw and the dispersity index (Mw/Mn) thereof were confirmed in accordance with the above-described GPC conditions. The polymer (A-30) corresponds to the above-described polymer (A2).

The type and the proportion in use, and the Mw and the Mw/Mn of the monomer that gives each structural unit of the polymers (A) obtained in Synthesis Examples 2-1 to 2-32 are shown in Table 1 below. In Table 1 below, “−” indicates that the corresponding monomer was not used.

TABLE 1

| | | | | | | Monomer | | Monomer | | | |
|---|---|---|---|---|---|---|---|---|---|---|---|
| | | Monomer | | Monomer | | that gives | | that gives | | | |
| | | that gives | | that gives | | structural unit | | other structural | | | |
| | | structural unit (I) | | structural unit (II) | | (III) | | unit | | | |
| | | | using | | using | | using | | using | | |
| | (A) | | amount | | amount | | amount | | amount | | |
| | Polymer | type | (mol %) | type | (mol %) | type | (mol %) | type | (mol %) | Mw | Mw/Mn |
| Synthesis | A-1 | X-1 | 20 | M-2 | 45 | M-8 | 35 | — | — | 5,900 | 1.5 |
| Example | | | | | | | | | | | |
| 2-1 | | | | | | | | | | | |
| Synthesis | A-2 | X-2 | 20 | M-2 | 45 | M-8 | 35 | — | — | 6,000 | 1.6 |
| Example | | | | | | | | | | | |
| 2-2 | | | | | | | | | | | |
| Synthesis | A-3 | X-3 | 20 | M-2 | 45 | M-8 | 35 | — | — | 6,200 | 1.5 |
| Example | | | | | | | | | | | |
| 2-3 | | | | | | | | | | | |
| Synthesis | A-4 | X-4 | 20 | M-2 | 45 | M-8 | 35 | — | — | 6,500 | 1.5 |
| Example | | | | | | | | | | | |
| 2-4 | | | | | | | | | | | |
| Synthesis | A-5 | X-5 | 20 | M-2 | 45 | M-8 | 35 | — | — | 6,300 | 1.5 |
| Example | | | | | | | | | | | |
| 2-5 | | | | | | | | | | | |
| Synthesis | A-6 | X-6 | 20 | M-2 | 45 | M-8 | 35 | — | — | 6,400 | 1.5 |
| Example | | | | | | | | | | | |
| 2-6 | | | | | | | | | | | |
| Synthesis | A-7 | X-7 | 20 | M-2 | 45 | M-8 | 35 | — | — | 6,500 | 1.5 |
| Example | | | | | | | | | | | |
| 2-7 | | | | | | | | | | | |
| Synthesis | A-8 | X-8 | 20 | M-2 | 45 | M-8 | 35 | — | — | 6,600 | 1.6 |
| Example | | | | | | | | | | | |
| 2-8 | | | | | | | | | | | |
| Synthesis | A-9 | X-9 | 20 | M-2 | 45 | M-8 | 35 | — | — | 6,500 | 1.6 |
| Example | | | | | | | | | | | |
| 2-9 | | | | | | | | | | | |
| Synthesis | A-10 | X-10 | 20 | M-2 | 45 | M-8 | 35 | — | — | 6,800 | 1.5 |
| Example | | | | | | | | | | | |
| 2-10 | | | | | | | | | | | |
| Synthesis | A-11 | X-11 | 20 | M-2 | 45 | M-8 | 35 | — | — | 6,200 | 1.5 |
| Example | | | | | | | | | | | |
| 2-11 | | | | | | | | | | | |
| Synthesis | A-12 | X-12 | 20 | M-2 | 45 | M-8 | 35 | — | — | 6,300 | 1.5 |
| Example | | | | | | | | | | | |
| 2-12 | | | | | | | | | | | |
| Synthesis | A-13 | X-1 | 55 | M-2 | 45 | — | — | — | — | 6,100 | 1.5 |
| Example | | | | | | | | | | | |
| 2-13 | | | | | | | | | | | |
| Synthesis | A-14 | X-2 | 55 | M-2 | 45 | — | — | — | — | 6,400 | 1.4 |
| Example | | | | | | | | | | | |
| 2-14 | | | | | | | | | | | |
| Synthesis | A-15 | X-3 | 55 | M-2 | 45 | — | — | — | — | 6,100 | 1.5 |
| Example | | | | | | | | | | | |
| 2-15 | | | | | | | | | | | |
| Synthesis | A-16 | X-7 | 55 | M-2 | 45 | — | — | — | — | 5,500 | 1.5 |
| Example | | | | | | | | | | | |
| 2-16 | | | | | | | | | | | |
| Synthesis | A-17 | X-1/X-9 | 20/35 | M-2 | 45 | — | — | — | — | 5,700 | 1.7 |
| Example | | | | | | | | | | | |
| 2-17 | | | | | | | | | | | |
| Synthesis | A-18 | X-1 | 20 | M-2 | 45 | M-7 | 35 | — | — | 5,600 | 1.5 |
| Example | | | | | | | | | | | |
| 2-18 | | | | | | | | | | | |
| Synthesis | A-19 | X-1 | 20 | M-2 | 45 | M-9 | 35 | — | — | 5,900 | 1.6 |
| Example | | | | | | | | | | | |
| 2-19 | | | | | | | | | | | |
| Synthesis | A-20 | X-1 | 20 | M-2 | 45 | M-10 | 35 | — | — | 6,100 | 1.6 |
| Example | | | | | | | | | | | |
| 2-20 | | | | | | | | | | | |
| Synthesis | A-21 | X-1 | 20 | M-2 | 45 | M-11 | 35 | — | — | 6,100 | 1.5 |
| Example | | | | | | | | | | | |
| 2-21 | | | | | | | | | | | |
| Synthesis | A-22 | X-1 | 20 | M-2 | 45 | M-12 | 35 | — | — | 6,200 | 1.6 |
| Example | | | | | | | | | | | |
| 2-22 | | | | | | | | | | | |
| Synthesis | A-23 | X-1 | 20 | M-2 | 45 | M-13 | 35 | — | — | 6,300 | 1.6 |
| Example | | | | | | | | | | | |
| 2-23 | | | | | | | | | | | |
| Synthesis | A-24 | X-1 | 20 | M-2/M-3 | 25/20 | M-8 | 35 | — | — | 5,500 | 1.6 |
| Example | | | | | | | | | | | |
| 2-24 | | | | | | | | | | | |
| Synthesis | A-25 | X-1 | 20 | M-2/M-1 | 25/20 | M-8 | 35 | — | — | 5,200 | 1.6 |
| Example | | | | | | | | | | | |
| 2-25 | | | | | | | | | | | |
| Synthesis | A-26 | X-1 | 20 | M-2/M-4 | 25/20 | M-8 | 35 | — | — | 5,700 | 1.5 |
| Example | | | | | | | | | | | |
| 2-26 | | | | | | | | | | | |
| Synthesis | A-27 | X-1 | 20 | M-2 | 25 | M-8 | 35 | M-5 | 20 | 6,500 | 1.5 |
| Example | | | | | | | | | | | |
| 2-27 | | | | | | | | | | | |
| Synthesis | A-28 | X-1 | 20 | M-2/M-6 | 25/20 | M-8 | 35 | — | — | 6,100 | 1.5 |
| Example | | | | | | | | | | | |
| 2-28 | | | | | | | | | | | |
| Synthesis | A-29 | X-1 | 20 | M-2 | 25 | M-8 | 35 | M-14 | 20 | 6,000 | 1.5 |
| Example | | | | | | | | | | | |
| 2-29 | | | | | | | | | | | |
| Synthesis | CA-1 | — | — | M-2 | 45 | CX-1 | 55 | — | — | 5,500 | 1.5 |
| Example | | | | | | | | | | | |
| 2-30 | | | | | | | | | | | |
| Synthesis | CA-2 | — | — | M-2 | 45 | CX-2 | 55 | — | — | 5,400 | 1.5 |
| Example | | | | | | | | | | | |
| 2-31 | | | | | | | | | | | |
| Synthesis | A-30 | X-1 | 20 | M-15 | 37 | M-8 | 35 | M-16 | 8 | 5,800 | 1.7 |
| Example | | | | | | | | | | | |
| 2-32 | | | | | | | | | | | |

### Synthesis of Polymer (F)

According to the following procedure, a polymer (F-1) to serve as the polymer (F) was synthesized. For synthesis of the polymer (F), the above monomer (M-9) and a compound (hereinafter, may be also referred to as “monomer (M-17)”) represented by the following formula (M-17) were used.

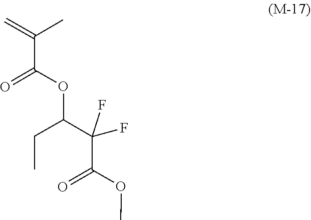 [SMILES: C=C(C)C(=O)OC(CC)C(F)(F)C(=O)OC]

### Synthesis Example 3: Synthesis of Polymer (F-1)

The monomer (M-9) and the monomer (M-17) were dissolved in 2-butanone (100 parts by mass) such that a molar ratio of the monomers became 40/60. Thereto was added as an initiator, azobis(isobutyronitrile) (5 mol %) to prepare a monomer solution. 2-butanone (50 parts by mass) was charged into an empty reaction vessel, and nitrogen was purged for 30 min. The interior of this reaction vessel was heated to 80° C., and the monomer solution was added dropwise over 3 hours with stirring. After completion of the dropwise addition, the solution was further heated at 80° C. for 3 hours, and then the polymerization solution was cooled to 30° C. or lower. After the polymerization solution was transferred into a separatory funnel, hexane (150 parts by mass) was added to homogenously dilute the polymerization solution. Furthermore, methanol (600 parts by mass) and water (30 parts by mass) were charged and mixed. After the mixture was left to stand for 30 min, the underlayer was recovered and the solvent was substituted with propylene glycol monomethyl ether acetate. In this manner, a 10% solution of the polymer (F-1) in propylene glycol monomethyl ether acetate was obtained. The polymer (F-1) had Mw=7,200, and Mw/Mn=1.7.

### Preparation of Radiation-Sensitive Composition

The acid generating agent (B), the acid diffusion control agent (C), and the organic solvent (D) used in preparation of the radiation-sensitive composition are shown below. In the following Examples and Comparative Examples, unless otherwise specified particularly, the term “parts by mass” means a value, provided that the mass of the polymer (A) used was 100 parts by mass, and the term “mol %” means a value, provided that the mol number of the anionic moiety of the acid generating agent (B) used accounted for 100 mol %.

### (B) Acid Generating Agent

Compounds (hereinafter, may be also referred to as “acid generating agents (B-1) to (B-12)”) represented by the following formulae (B-1) to (B-12) were used as the acid generating agent (B). The acid generating agents (B-1) to (B-9) correspond to the compound (Z). The acid generating agent (B-11) is a compound having an anionic moiety including two types of anion groups, i.e., a sulfonic acid anion group and a nitrogen anion group (—N—).

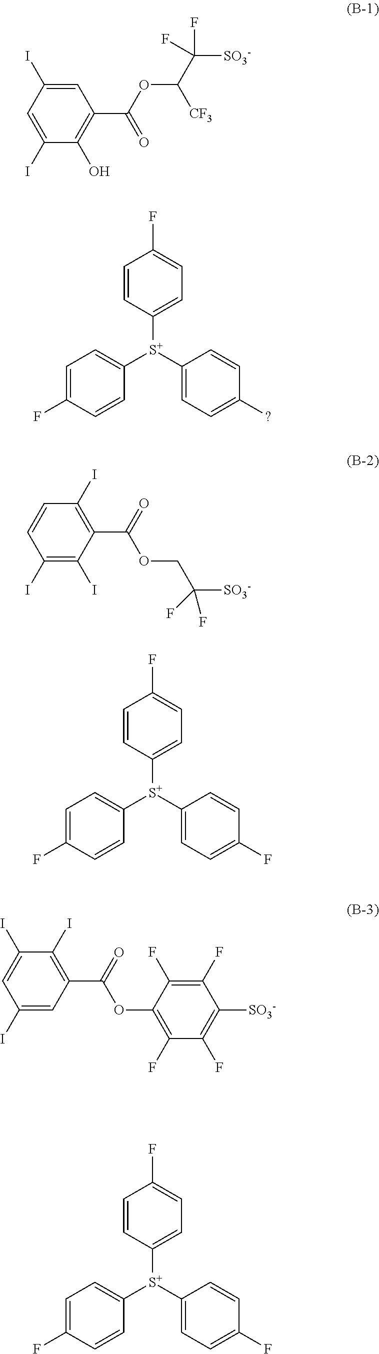

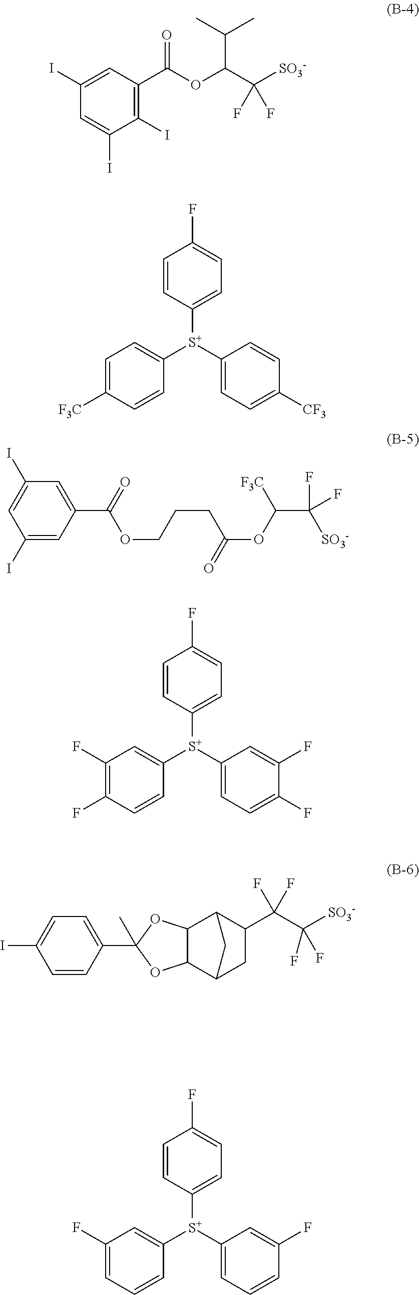

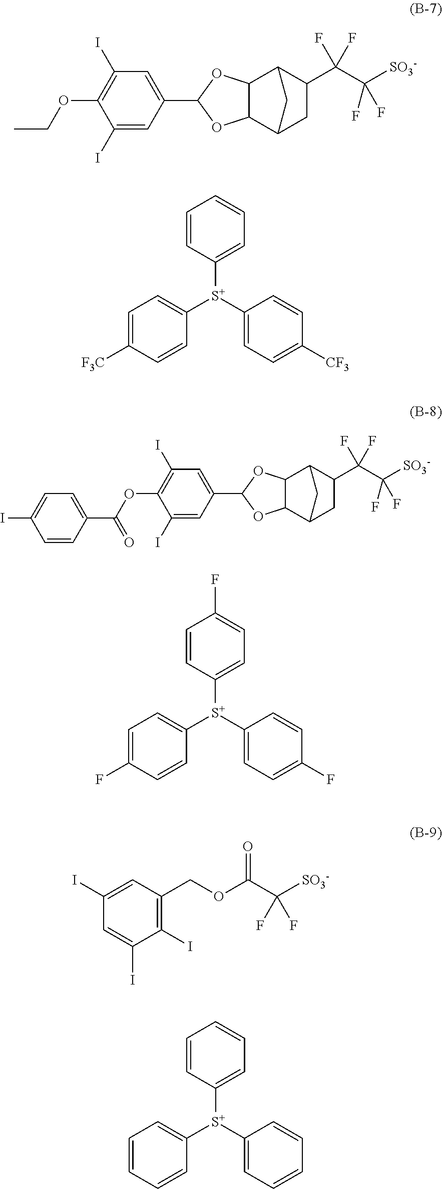

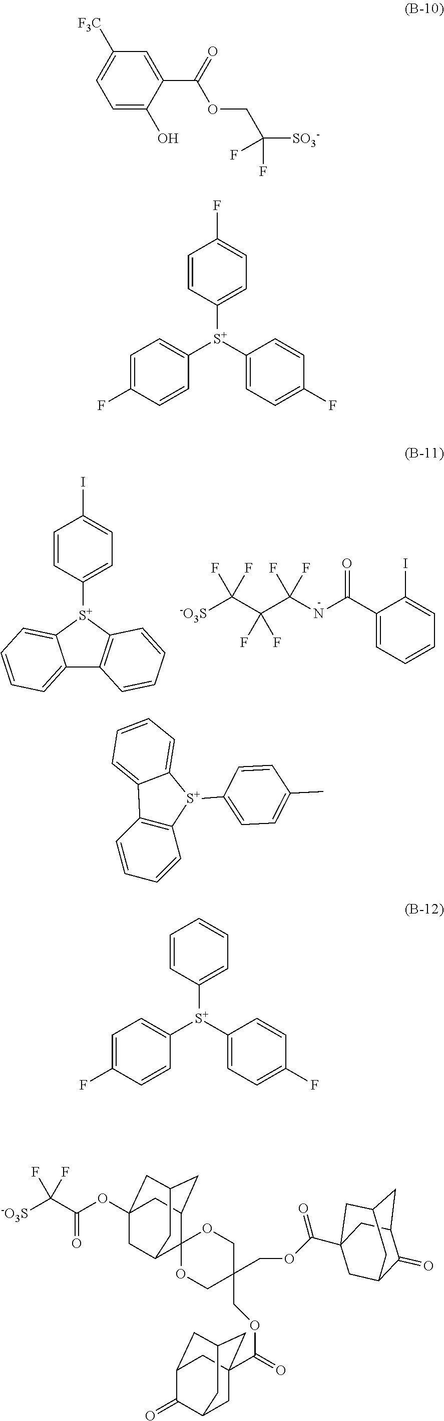

### (C) Acid Diffusion Control Agent

Compounds (hereinafter, may be also referred to as “acid diffusion control agents (C-1) to (C-7)”) represented by the following formulae (C-1) to (C-7) were used as the acid diffusion control agent (C). The acid diffusion control agents (C-6) and (C-7) correspond to the compound (Z).

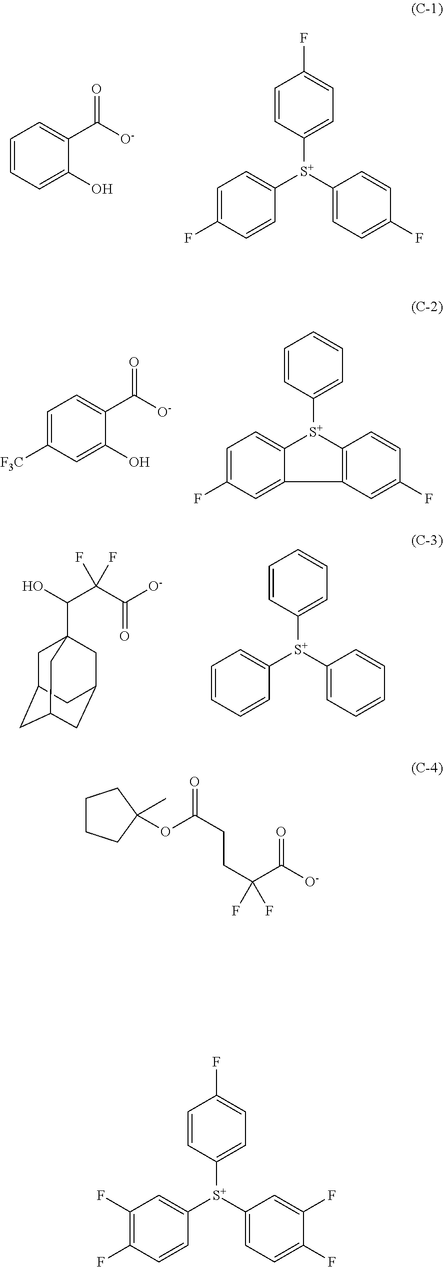

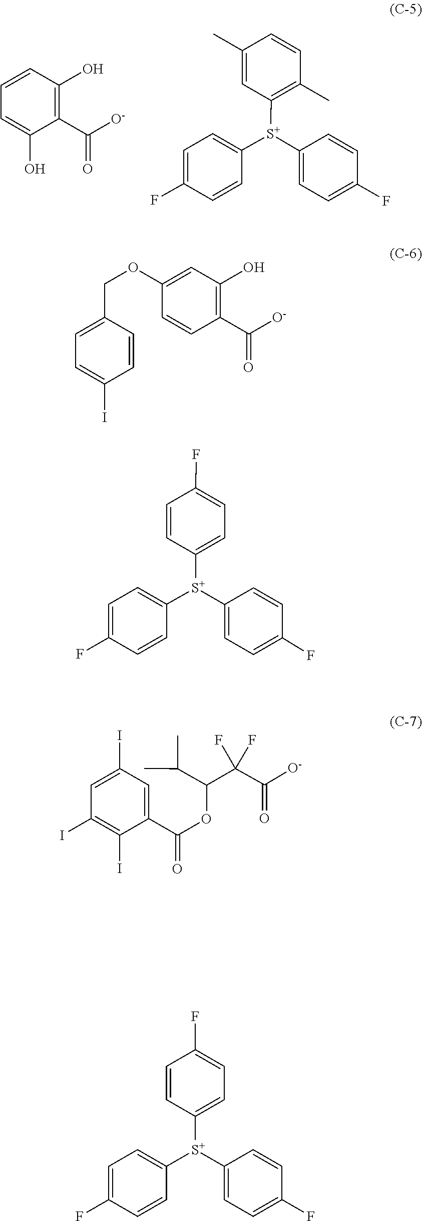 [SMILES: O=C([O-])c1c(O)cccc1O ; Cc1ccc(C)c([S+](c2ccc(F)cc2)c2ccc(F)cc2)c1 ; O=C([O-])c1ccc(OCc2ccc(I)cc2)cc1O ; Fc1ccc([S+](c2ccc(F)cc2)c2ccc(F)cc2)cc1 ; CC(C)C(OC(=O)c1cc(I)cc(I)c1I)C(F)(F)C(=O)[O-] ; Fc1ccc([S+](c2ccc(F)cc2)c2ccc(F)cc2)cc1]

### (D) Organic Solvent

The following organic solvents were used as the organic solvent (D).
(D-1): propylene glycol monomethyl ether acetate
(D-2): propylene glycol monomethyl ether

### Example 1: Preparation of Radiation-Sensitive Composition (R-1)

100 parts by mass of the polymer (A-1) to serve as the polymer (A), 3 parts by mass of the polymer (F-1) to serve as the polymer (F), 45 parts by mass of the acid generating agent (B-1) to serve as the acid generating agent (B), the acid diffusion control agent (C-1) to serve as the acid diffusion control agent (C) in an amount of 50 mol % with respect to the anionic moiety of the acid generating agent (B-1), and 5,500 parts by mass of (D-1) and 1,500 parts by mass of (D-2) to serve as the organic solvent (D) were mixed. A mix liquid thus obtained was filtered through a membrane filter having a pore size of 0.20 μm, whereby a radiation-sensitive composition (R-1) was prepared.

### Examples 2 to 45 and Comparative Examples 1 to 6: Preparation of Radiation-Sensitive Compositions (R-2) to (R-45) and (CR-1) to (CR-6)

Radiation-sensitive compositions (R-2) to (R-45) and (CR-1) to (CR-6) were prepared in a similar manner to Example 1 except that each component of the type and in the content shown in Table 2 below was used.

TABLE 2

| | | | | | | (B) Acid | | | | | |
|---|---|---|---|---|---|---|---|---|---|---|---|
| | | | | | | generating | | | | | |
| | | | | (F) Polymer | | agent | | (C) Acid | | | |
| | | (A) Polymer | | | content | | content | diffusion | | (D) Solvent | |
| | Radiation- | | content | | (parts | | (parts | control agent | | | content |
| | sensitive | | (parts | | by | | by | | content | | (parts |
| | composition | type | by mass) | type | mass) | type | mass) | type | (mol %) | type | by mass) |
| Example 1 | R-1 | A-1 | 100 | F-1 | 3 | B-1 | 45 | C-1 | 50 | D-1/D-2 | 5500/1500 |
| Example 2 | R-2 | A-2 | 100 | F-1 | 3 | B-1 | 45 | C-1 | 50 | D-1/D-2 | 5500/1500 |
| Example 3 | R-3 | A-3 | 100 | F-1 | 3 | B-1 | 45 | C-1 | 50 | D-1/D-2 | 5500/1500 |
| Example 4 | R-4 | A-4 | 100 | F-1 | 3 | B-1 | 45 | C-1 | 50 | D-1/D-2 | 5500/1500 |
| Example 5 | R-5 | A-5 | 100 | F-1 | 3 | B-1 | 45 | C-1 | 50 | D-1/D-2 | 5500/1500 |
| Example 6 | R-6 | A-6 | 100 | F-1 | 3 | B-1 | 45 | C-1 | 50 | D-1/D-2 | 5500/1500 |
| Example 7 | R-7 | A-7 | 100 | F-1 | 3 | B-1 | 45 | C-1 | 50 | D-1/D-2 | 5500/1500 |
| Example 8 | R-8 | A-8 | 100 | F-1 | 3 | B-1 | 45 | C-1 | 50 | D-1/D-2 | 5500/1500 |
| Example 9 | R-9 | A-9 | 100 | F-1 | 3 | B-1 | 45 | C-1 | 50 | D-1/D-2 | 5500/1500 |
| Example 10 | R-10 | A-10 | 100 | F-1 | 3 | B-1 | 45 | C-1 | 50 | D-1/D-2 | 5500/1500 |
| Example 11 | R-11 | A-11 | 100 | F-1 | 3 | B-1 | 45 | C-1 | 50 | D-1/D-2 | 5500/1500 |
| Example 12 | R-12 | A-12 | 100 | F-1 | 3 | B-1 | 45 | C-1 | 50 | D-1/D-2 | 5500/1500 |
| Example 13 | R-13 | A-13 | 100 | F-1 | 3 | B-1 | 45 | C-1 | 50 | D-1/D-2 | 5500/1500 |
| Example 14 | R-14 | A-14 | 100 | F-1 | 3 | B-1 | 45 | C-1 | 50 | D-1/D-2 | 5500/1500 |
| Example 15 | R-15 | A-15 | 100 | F-1 | 3 | B-1 | 45 | C-1 | 50 | D-1/D-2 | 5500/1500 |
| Example 16 | R-16 | A-16 | 100 | F-1 | 3 | B-1 | 45 | C-1 | 50 | D-1/D-2 | 5500/1500 |
| Example 17 | R-17 | A-17 | 100 | F-1 | 3 | B-1 | 45 | C-1 | 50 | D-1/D-2 | 5500/1500 |
| Example 18 | R-18 | A-18 | 100 | F-1 | 3 | B-1 | 45 | C-1 | 50 | D-1/D-2 | 5500/1500 |
| Example 19 | R-19 | A-19 | 100 | F-1 | 3 | B-1 | 45 | C-1 | 50 | D-1/D-2 | 5500/1500 |
| Example 20 | R-20 | A-20 | 100 | F-1 | 3 | B-1 | 45 | C-1 | 50 | D-1/D-2 | 5500/1500 |
| Example 21 | R-21 | A-21 | 100 | F-1 | 3 | B-1 | 45 | C-1 | 50 | D-1/D-2 | 5500/1500 |
| Example 22 | R-22 | A-22 | 100 | F-1 | 3 | B-1 | 45 | C-1 | 50 | D-1/D-2 | 5500/1500 |
| Example 23 | R-23 | A-23 | 100 | F-1 | 3 | B-1 | 45 | C-1 | 50 | D-1/D-2 | 5500/1500 |
| Example 24 | R-24 | A-24 | 100 | F-1 | 3 | B-1 | 45 | C-1 | 50 | D-1/D-2 | 5500/1500 |
| Example 25 | R-25 | A-25 | 100 | F-1 | 3 | B-1 | 45 | C-1 | 50 | D-1/D-2 | 5500/1500 |
| Example 26 | R-26 | A-26 | 100 | F-1 | 3 | B-1 | 45 | C-1 | 50 | D-1/D-2 | 5500/1500 |
| Example 27 | R-27 | A-27 | 100 | F-1 | 3 | B-1 | 45 | C-1 | 50 | D-1/D-2 | 5500/1500 |
| Example 28 | R-28 | A-28 | 100 | F-1 | 3 | B-1 | 45 | C-1 | 50 | D-1/D-2 | 5500/1500 |
| Example 29 | R-29 | A-29 | 100 | F-1 | 3 | B-1 | 45 | C-1 | 50 | D-1/D-2 | 5500/1500 |
| Example 30 | R-30 | A-1 | 100 | F-1 | 3 | B-2 | 45 | C-1 | 50 | D-1/D-2 | 5500/1500 |
| Example 31 | R-31 | A-1 | 100 | F-1 | 3 | B-3 | 45 | C-1 | 50 | D-1/D-2 | 5500/1500 |
| Example 32 | R-32 | A-1 | 100 | F-1 | 3 | B-4 | 45 | C-1 | 50 | D-1/D-2 | 5500/1500 |
| Example 33 | R-33 | A-1 | 100 | F-1 | 3 | B-5 | 45 | C-1 | 50 | D-1/D-2 | 5500/1500 |
| Example 34 | R-34 | A-1 | 100 | F-1 | 3 | B-6 | 45 | C-1 | 50 | D-1/D-2 | 5500/1500 |
| Example 35 | R-35 | A-1 | 100 | F-1 | 3 | B-7 | 45 | C-1 | 50 | D-1/D-2 | 5500/1500 |
| Example 36 | R-36 | A-1 | 100 | F-1 | 3 | B-8 | 45 | C-1 | 50 | D-1/D-2 | 5500/1500 |
| Example 37 | R-37 | A-1 | 100 | F-1 | 3 | B-9 | 45 | C-1 | 50 | D-1/D-2 | 5500/1500 |
| Example 38 | R-38 | A-1 | 100 | F-1 | 3 | B-1 | 45 | C-2 | 50 | D-1/D-2 | 5500/1500 |
| Example 39 | R-39 | A-1 | 100 | F-1 | 3 | B-1 | 45 | C-3 | 50 | D-1/D-2 | 5500/1500 |
| Example 40 | R-40 | A-1 | 100 | F-1 | 3 | B-1 | 45 | C-4 | 50 | D-1/D-2 | 5500/1500 |
| Example 41 | R-41 | A-1 | 100 | F-1 | 3 | B-1 | 45 | C-5 | 50 | D-1/D-2 | 5500/1500 |
| Example 42 | R-42 | A-1 | 100 | F-1 | 3 | B-1 | 45 | C-6 | 50 | D-1/D-2 | 5500/1500 |
| Example 43 | R-43 | A-1 | 100 | F-1 | 3 | B-1 | 45 | C-7 | 50 | D-1/D-2 | 5500/1500 |
| Example 44 | R-44 | A-1 | 100 | F-1 | 3 | B-10 | 45 | C-6 | 50 | D-1/D-2 | 5500/1500 |
| Comparative | CR-1 | A-1 | 100 | F-1 | 3 | B-10 | 45 | C-1 | 50 | D-1/D-2 | 5500/1500 |
| Example 1 | | | | | | | | | | | |
| Comparative | CR-2 | A-1 | 100 | F-1 | 3 | B-11 | 45 | C-1 | 50 | D-1/D-2 | 5500/1500 |
| Example 2 | | | | | | | | | | | |
| Comparative | CR-3 | A-1 | 100 | F-1 | 3 | B-12 | 45 | C-1 | 50 | D-1/D-2 | 5500/1500 |
| Example 3 | | | | | | | | | | | |
| Comparative | CR-4 | CA-1 | 100 | F-1 | 3 | B-1 | 45 | C-1 | 50 | D-1/D-2 | 5500/1500 |
| Example 4 | | | | | | | | | | | |
| Comparative | CR-5 | CA-2 | 100 | F-1 | 3 | B-1 | 45 | C-1 | 50 | D-1/D-2 | 5500/1500 |
| Example 5 | | | | | | | | | | | |
| Comparative | CR-6 | CA-1 | 100 | F-1 | 3 | B-10 | 45 | C-1 | 50 | D-1/D-2 | 5500/1500 |
| Example 6 | | | | | | | | | | | |
| Example 45 | R-45 | A-30 | 100 | F-1 | 3 | - | - | C-1 | 50 | D-1/D-2 | 5500/1500 |

### Formation of Resist Pattern

By using a spin coater (“CLEAN TRACK ACT 12” available from Tokyo Electron Limited), the radiation-sensitive composition prepared as described above was applied on a 12-inch silicon wafer surface provided with an underlayer film (“AL412” available from Brewer Science, Inc.) having an average thickness of 20 nm formed thereon. A resist film having an average thickness of 30 nm was formed through PB carried out at 100° C. for 60 sec, followed by cooling at 23° C. for 30 sec. This resist film was irradiated with EUV light by using an EUV scanner (“NXE3300” available from ASML Co.: NA=0.33, irradiation condition: Conventional s=0.89). The resist film was subjected to PEB at 100° C. for 60 sec. Development was performed using a 2.38% by mass aqueous TMAH solution at 23° C. for 30 sec to form a positive-tone contact hole pattern with 50 nm pitch and 25 nm holes.

### Evaluations

The sensitivity, the CDU, and the inhibitory ability of development defects were evaluated in accordance with the following methods. Line-width measurement of the resist pattern was performed using a scanning electron microscope (“CG-4100” available from Hitachi High-Tech Corporation). The results of the evaluations are shown in Table 3 below.

### Sensitivity

An exposure dose at which the contact hole pattern with 25 nm holes was formed in the aforementioned Formation of Resist Pattern was defined as an optimum exposure dose, and this optimum exposure dose was adopted as the sensitivity (mJ/cm²). The optimum exposure dose value being smaller indicates more favorable sensitivity. The sensitivity was evaluated to be: “A” (extremely favorable) in a case of less than 60 mJ/cm²; “B” (favorable) in a case of no less than 60 mJ/cm² and no greater than 63 mJ/cm²; and “C” (poor) in a case of greater than 63 mJ/cm².

### CDU

The contact hole pattern with 25 nm holes was observed from above using the scanning electron microscope. Diameters in the contact hole pattern were measured at arbitrary 800 sites in total, and then a 3 Sigma value was determined from distribution of the measurement values and was defined as CDU (unit: nm). The CDU value being smaller indicates more favorable CDU, revealing less variance of the hole diameters in greater ranges. The CDU was evaluated to be: “A” (extremely favorable) in a case of the CDU being less than 3.5 nm; “B” (favorable) in a case of the CDU being no less than 3.5 nm and less than 3.7 nm; and “C” (poor) in a case of the CDU being no less than 3.7 nm.

### Inhibitory Ability of Development Defects

The resist film was exposed at the optimum exposure dose determined in the above section of “Sensitivity”, and developed to form a contact hole pattern with 25 nm holes. The number of defects on the wafer was measured using a defect inspection device (“KLA2810” available from KLA-Tencor Corporation). The defects counted in the measurement described above were classified into: defects assessed as deriving from the resist film; and foreign matter deriving from an outer environment. The inhibitory ability of development defects was evaluated to be: “A” (extremely favorable) in a case in which the number of the defects assessed as deriving from the resist film was less than 30; “B” (favorable) in a case in which the number was no less than 30 and no greater than 50; and “C” (poor) in a case in which the number was greater than 50.

TABLE 3

| | Radiation- | | | |
|---|---|---|---|---|
| | Sensitive | | | Inhibitory ability |
| | composition | Sensitivity | CDU performance | of development defects |
| Example 1 | R-1 | B | A | B |
| Example 2 | R-2 | B | A | B |
| Example 3 | R-3 | B | A | B |
| Example 4 | R-4 | B | A | B |
| Example 5 | R-5 | B | A | B |
| Example 6 | R-6 | B | A | B |
| Example 7 | R-7 | B | A | B |
| Example 8 | R-8 | A | A | B |
| Example 9 | R-9 | B | B | B |
| Example 10 | R-10 | B | A | A |
| Example 11 | R-11 | B | A | B |
| Example 12 | R-12 | B | A | B |
| Example 13 | R-13 | A | A | A |
| Example 14 | R-14 | A | A | A |
| Example 15 | R-15 | A | A | A |
| Example 16 | R-16 | A | A | A |
| Example 17 | R-17 | B | A | A |
| Example 18 | R-18 | B | A | B |
| Example 19 | R-19 | B | A | B |
| Example 20 | R-20 | B | B | B |
| Example 21 | R-21 | A | A | B |
| Example 22 | R-22 | A | A | B |
| Example 23 | R-23 | B | A | B |
| Example 24 | R-24 | B | A | B |
| Example 25 | R-25 | B | A | B |
| Example 26 | R-26 | A | B | A |
| Example 27 | R-27 | B | B | B |
| Example 28 | R-28 | B | A | B |
| Example 29 | R-29 | B | B | B |
| Example 30 | R-30 | B | B | B |
| Example 31 | R-31 | B | B | B |
| Example 32 | R-32 | A | A | B |
| Example 33 | R-33 | A | A | B |
| Example 34 | R-34 | B | B | B |
| Example 35 | R-35 | A | A | B |
| Example 36 | R-36 | A | A | B |
| Example 37 | R-37 | B | A | B |
| Example 38 | R-38 | B | A | B |
| Example 39 | R-39 | B | A | B |
| Example 40 | R-40 | A | A | B |
| Example 41 | R-41 | B | A | B |
| Example 42 | R-42 | A | A | A |
| Example 43 | R-43 | A | A | B |
| Example 44 | R-44 | B | B | B |
| Comparative Example 1 | CR-1 | C | C | B |
| Comparative Example 2 | CR-2 | C | C | B |
| Comparative Example 3 | CR-3 | C | C | B |
| Comparative Example 4 | CR-4 | C | B | C |
| Comparative Example 5 | CR-5 | C | C | B |
| Comparative Example 6 | CR-6 | C | C | C |
| Example 45 | R-45 | A | A | A |

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive composition comprising:
a polymer comprising a first structural unit comprising a partial structure obtained by substituting a hydrogen atom of a carboxy group or a hydrogen atom of a phenolic hydroxyl group, with an acid-labile group represented by formula (1); and
a compound comprising an anionic moiety and a radiation-sensitive onium cationic moiety, the anionic moiety comprising one anion group and an aromatic ring in which at least one hydrogen atom is substituted with an iodine atom, 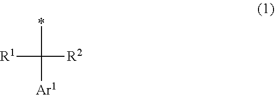
wherein, in the formula (1), Ar¹ represents a group obtained by removing one hydrogen atom from an aromatic ring in which at least one hydrogen atom is substituted with an iodine atom;
R¹ and R² each independently represent a hydrogen atom or a substituted or unsubstituted monovalent hydrocarbon group having 1 to 20 carbon atoms, wherein a case in which R¹ and R² each represent a hydrogen atom is excluded, or R¹ and R² taken together represent an alicyclic ring having 3 to 20 ring atoms, together with the carbon atom to which R¹ and R² bond; and
* denotes a site bonding to an ethereal oxygen atom of the carboxy group or to an oxygen atom of the phenolic hydroxyl group.

2. The radiation-sensitive composition according to claim 1, wherein the anionic moiety is a monovalent anion.

3. The radiation-sensitive composition according to claim 1, wherein the one anion group is a sulfonic acid group.

4. The radiation-sensitive composition according to claim 1, wherein the aromatic ring that gives Ar¹ is an aromatic hydrocarbon ring.

5. The radiation-sensitive composition according to claim 1, wherein the polymer further comprises a second structural unit comprising a phenolic hydroxyl group.

6. A radiation-sensitive composition comprising:
a polymer comprising:
a structural unit comprising a partial structure obtained by substituting a hydrogen atom of a carboxy group or a hydrogen atom of a phenolic hydroxyl group, with an acid-labile group represented by formula (1); and
a structural unit comprising an anionic moiety and a radiation-sensitive onium cationic moiety, the anionic moiety comprising one anion group, and an aromatic ring in which at least one hydrogen atom is substituted with an iodine atom, 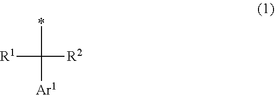
wherein, in the formula (1), Ar¹ represents a group obtained by removing one hydrogen atom from an aromatic ring in which at least one hydrogen atom is substituted with an iodine atom;
R¹ and R² each independently represent a hydrogen atom or a substituted or unsubstituted monovalent hydrocarbon group having 1 to 20 carbon atoms, wherein a case in which R¹ and R² each represent a hydrogen atom is excluded, or R¹ and R² taken together represent an alicyclic ring having 3 to 20 ring atoms, together with the carbon atom to which R¹ and R² bond; and
* denotes a site bonding to an ethereal oxygen atom of the carboxy group or to an oxygen atom of the phenolic hydroxyl group.

7. A method of forming a resist pattern, the method comprising:
applying the radiation-sensitive composition according to claim 1 directly or indirectly on a substrate to form a resist film;
exposing the resist film; and
developing the resist film exposed.

8. A method of forming a resist pattern, the method comprising:
applying the radiation-sensitive composition according to claim 6 directly or indirectly on a substrate to form a resist film;
exposing the resist film; and
developing the resist film exposed.
